(19) United States
(12) Patent Application Publication
(10) Pub. No.: US 2025/0338704 A1
(43) Pub. Date: Oct. 30, 2025

(54) PEROVSKITE PHOTODIODE AND IMAGE SENSOR AND ELECTRONIC DEVICE

(71) Applicants: Samsung Electronics Co., Ltd., Suwon-si (KR); IUCF-HYU (Industry-University Cooperation Foundation Hanyang University), Seoul (KR)

(72) Inventors: Hui Joon PARK, Seoul (KR); Seon-Jeong LIM, Suwon-si (KR); Han Sol PARK, Seoul (KR); Hyerim HONG, Suwon-si (KR)

(73) Assignees: Samsung Electronics Co., Ltd., Suwon-si (KR); IUCF-HYU (Industry-University Cooperation Foundation Hanyang University), Seoul (KR)

(21) Appl. No.: 18/977,290

(22) Filed: Dec. 11, 2024

(30) Foreign Application Priority Data
Apr. 29, 2024 (KR) 10-2024-0056657

(51) Int. Cl. H10K 30/84; H10K 30/60; H10K 39/32; H10K 85/50; H10K 85/60

(52) U.S. Cl. CPC H10K 30/84; H10K 30/60; H10K 39/32; H10K 85/50; H10K 85/6572

(57) ABSTRACT

A perovskite photodiode includes a first electrode and a second electrode, a perovskite photoelectric conversion layer between the first electrode and the second electrode and including a Pb-free perovskite represented by Chemical Formula 1, and an auxiliary layer between the first electrode and the perovskite photoelectric conversion layer and including an organic compound represented by Chemical Formula 2.

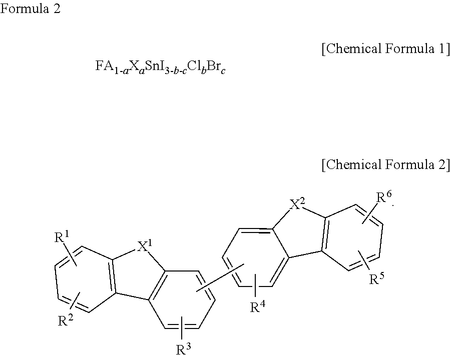

### CROSS-REFERENCE TO RELATED APPLICATION

This application claims priority to and the benefit of Korean Patent Application No. 10-2024-0056657 filed in the Korean Intellectual Property Office on Apr. 29, 2024, the entire contents of which are incorporated herein by reference.

### BACKGROUND

### 1. Field

Example embodiments of the inventive concepts are directed to perovskite photodiodes, image sensors (e.g., image sensors including perovskite photodiodes), and electronic devices (e.g., electronic devices including images sensors, where the image sensors included in the electronic devices include perovskite photodiodes).

### 2. Description of the Related Art

An imaging device such as a camera includes an imaging device that captures an image and stores the captured image as an electrical signal. The imaging device includes an image sensor that decomposes (e.g., absorbs) incident light according to a wavelength to convert each component (e.g., the absorbed light according to wavelength) into an electrical signal. Currently, commercialized image sensors are mainly crystalline silicon-based image sensors.

### SUMMARY

However, since crystalline silicon has a light absorption characteristic of a wide-ranged wavelength spectrum of about 200 nm to about 1400 nm, it is difficult to implement wavelength selectivity and there are limitations in the process. In some example embodiments, photodiodes capable of replacing crystalline silicon and being applied to an image sensor are provided. Such photodiodes may provide improved wavelength selectively in relation to crystalline silicon-based image sensors, wherein crystalline silicon has a light absorption characteristic of a wide-ranged wavelength spectrum of about 200 nm to about 1400 nm.

Some example embodiments provide a perovskite photodiode capable of increasing wavelength selectivity, widening process selectivity, and improving electrical characteristics in relation to crystalline silicon photodiodes and/or organic photoelectric conversion devices with a simple structure.

Some example embodiments provide an image sensor including the perovskite photodiode.

Some example embodiments provide an electronic device including the perovskite photodiode or the image sensor.

According to some example embodiments, a perovskite photodiode may include a first electrode and a second electrode, a perovskite photoelectric conversion layer between the first electrode and the second electrode and including a Pb-free perovskite represented by Chemical Formula 1, and an auxiliary layer between the first electrode and the perovskite photoelectric conversion layer and including an organic compound represented by Chemical Formula 2.

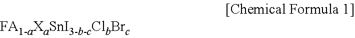

In Chemical Formula 1,
FA is formamidinium,
X is a substituted or unsubstituted methyl ammonium, a substituted or unsubstituted ethylene diammonium, a substituted or unsubstituted C6 to C12 aromatic alkylammonium, a substituted or unsubstituted C1 to C10 aliphatic ammonium, Cs⁺, Rb⁺, K⁺, Na⁺, or any combination thereof,
0≤a≤1, 0≤b≤1, and 0≤c≤1, and
at least one of b or c is not 0,

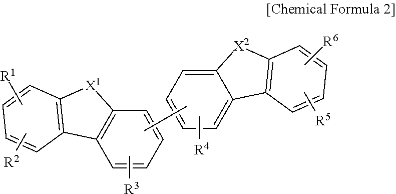

wherein, in Chemical Formula 2,
X¹ and X² are different from each other, and X¹ and X² are each independently one of CR^{a}R^{b}, SiR^{c}R^{d}, or NR^{e},
R¹ to R⁶ are each independently hydrogen, a substituted or unsubstituted C1 to C30 alkyl group, a substituted or unsubstituted C1 to C30 alkoxy group, a substituted or unsubstituted C6 to C20 aryl group, a substituted or unsubstituted C3 to C20 heterocyclic group, a halogen, a cyano group, —NR^{f}R^{g}, or any combination thereof,
at least one of R¹ or R⁶ is a substituted or unsubstituted C6 to C20 aryl group, a substituted or unsubstituted C3 to C20 heterocyclic group, —NR^{f}R^{g}, or any combination thereof,
R^{a} to R^{g} are each independently hydrogen, a substituted or unsubstituted C1 to C30 alkyl group, a substituted or unsubstituted C6 to C20 aryl group, a substituted or unsubstituted C3 to C20 heterocyclic group, a halogen, a cyano group, or any combination thereof,
R^{a} and R^{b} are each independently present or are combined with each other to form a first ring,
R^{c} and R^{d} are each independently present or are combined with each other to form a second ring, and
R^{f} and R^{g} are each independently present or are combined with each other to form a third ring.

In Chemical Formula 1, a, b, and c may satisfy 0<a≤0.5 and 0<(b+c)≤0.5.

The Pb-free perovskite may include FA₁₋ₐMAₐSnI_{3-b-c}Cl_{b}Br_{c}, FA₁₋ₐEDAₐSnI_{3-b-c}Cl_{b}Br_{c}, FA₁₋ₐ(F-PEA)ₐSnI_{3-b-c}Cl_{b}Br_{c}, FA₁₋ₐ₁₋ₐ₂(MA)ₐ₁(EDA)ₐ₂SnI_{3-b-c}Cl_{b}Br_{c}, FA₁₋ₐ₁₋ₐ₂(MA)ₐ₁(Cs)ₐ₂SnI_{3-b-c}Cl_{b}Br_{c}, FA₁₋ₐ₁₋ₐ₂(EDA)ₐ₁(Cs)ₐ₂SnI_{3-b-c}Cl_{b}Br_{c}, FA₁₋ₐ₁₋ₐ₂(F-PEA)ₐ₁(Cs)ₐ₂SnI_{3-b-c}Cl_{b}Br_{c}, FA₁₋ₐ₁₋ₐ₂(MA)ₐ₁(EDA)ₐ₂SnI_{3-b-c}Cl_{b}Br_{c}, FA₁₋ₐ₁₋ₐ₂(F-PEA)ₐ₁(EDA)ₐ₂SnI_{3-b-c}Cl_{b}Br_{c}, FA₁₋ₐ₁₋ₐ₂(F-PEA)ₐ₁(MA)ₐ₂SnI_{3-b-c}Cl_{b}Br_{c}, or any combination thereof, wherein FA is formamidinium, MA is methyl ammonium, EDA is ethylene diammonium, F-PEA is fluorine-substituted phenethylammonium, and wherein 0<a≤0.5, 0<(a1+a2)≤0.5, 0≤a1≤0.5, 0≤a2≤0.5, 0≤b≤0.5, 0≤c≤0.5, and 0<(b+c)≤0.5.

X¹ in Chemical Formula 2 may be CR^{a}R^{b} or SiR^{c}R^{d}, wherein R^{a} to R^{d} may independently be hydrogen, a substituted or unsubstituted C1 to C30 alkyl group, or a substituted or unsubstituted C6 to C20 aryl group, X² in Chemical Formula 2 may be NR^{e}, wherein R^{e} may be a substituted or unsubstituted C6 to C20 aryl group.

R¹ and R⁶ in Chemical Formula 2 may each be —NR^{f}R^{g}, where R^{f} and R^{g} may each be a substituted or unsubstituted C6 to C20 aryl group, or R^{f} and R^{g} may be bonded to form a ring through a single bond, a substituted or unsubstituted C1 to C5 alkylene group, a substituted or unsubstituted C2 to C5 alkenylene group, a substituted or unsubstituted C6 to C20 arylene group, O, S, Se, Te, CR^{h}Rⁱ, SiR^{j}R^{k}, or GeR^{l}R^{m}, wherein R^{h} to R^{m} may each independently be hydrogen, a substituted or unsubstituted C1 to C30 alkyl group, a substituted or unsubstituted C6 to C20 aryl group, a substituted or unsubstituted C3 to C20 heterocyclic group, a halogen, a cyano group, or any combination thereof.

The organic compound may be represented by Chemical Formula 2A.

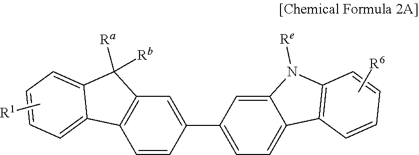

In Chemical Formula 2A,
R^{a} and R^{b} are each independently hydrogen, a substituted or unsubstituted C1 to C30 alkyl group or a substituted or unsubstituted C6 to C20 aryl group,
R^{e} is a substituted or unsubstituted C6 to C20 aryl group, and
R¹ and R⁶ are each one group of the plurality of groups listed in Group 1,

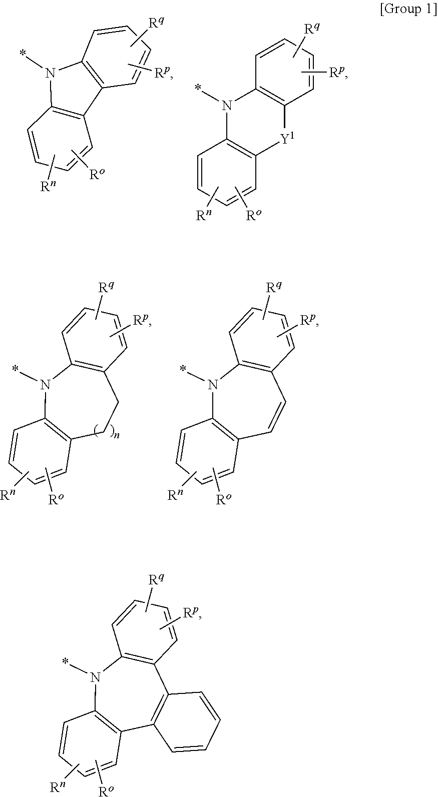

In Group 1,
Y¹ is O, S, Se, Te, CR^{h}Rⁱ, SiR^{j}R^{k}, or GeR^{l}R^{m},
R^{h} to R^{q} are each independently hydrogen, a substituted or unsubstituted C1 to C30 alkyl group, a substituted or unsubstituted C6 to C20 aryl group, a substituted or unsubstituted C3 to C20 heterocyclic group, a halogen, a cyano group, or any combination thereof,
n is an integer from 0 to 2, and
* is a linking point with Chemical Formula 2A.

According to some example embodiments, an image sensor may include the perovskite photodiode.

According to some example embodiments, an image sensor may include a substrate, a first perovskite photodiode on the substrate, and a wavelength selective filter layer overlapped with the first perovskite photodiode and including a plurality of wavelength selective filters, wherein the first perovskite photodiode includes a first electrode, a second electrode, a first perovskite photoelectric conversion layer between the first electrode and the second electrode and including a first Pb-free perovskite represented by Chemical Formula 1, and a first auxiliary layer between the first electrode and the first perovskite photoelectric conversion layer and including the organic compound represented by Chemical Formula 2.

The plurality of wavelength selective filters may be at least two of a blue filter, a green filter, a red filter, a cyan filter, a yellow filter, a magenta filter, or an infrared filter.

The first perovskite photodiode may include a blue perovskite photodiode configured to selectively sense light in a blue wavelength spectrum, a green perovskite photodiode configured to selectively sense light in a green wavelength spectrum, and a red perovskite photodiode configured to selectively sense light in a red wavelength spectrum, wherein the blue perovskite photodiode, the green perovskite photodiode, and the red perovskite photodiode are arranged along an in-plane direction of the substrate, the wavelength selective filter layer may include a first wavelength selective filter overlapped with the blue perovskite photodiode in a vertical direction perpendicular to an upper surface of the substrate, the first wavelength selective filter one of a blue filter, a cyan filter, or a magenta filter, a second wavelength selective filter overlapped with the green perovskite photodiode in the vertical direction, the second wavelength selective filter one of a green filter, a cyan filter, or a yellow filter, and a third wavelength selective filter overlapped with the red perovskite photodiode in the vertical direction, the third wavelength selective filter one of a red filter, a yellow filter, or a magenta filter, wherein the first wavelength selective filter, the second wavelength selective filter, and the third wavelength selective filter may be different from each other.

The blue perovskite photodiode, the green perovskite photodiode, and the red perovskite photodiode include separate, respective portions of the first perovskite photoelectric conversion layer, and a cut-off wavelength of the absorption spectrum of the first Pb-free perovskite may belong to more than about 650 nm and less than about 750 nm.

The first perovskite photodiode may further include an infrared perovskite photodiode configured to selectively sense light of an infrared wavelength spectrum, the infrared perovskite photodiode may be arranged in parallel with the blue perovskite photodiode, the green perovskite photodiode, or the red perovskite photodiode along an in-plane direction of the substrate, and the wavelength selective filter layer may further include an infrared filter arranged in parallel with the first wavelength selective filter, the second wavelength selective filter, and the third wavelength selective filter, the infrared filter overlapped with the infrared perovskite photodiode in the vertical direction.

The blue perovskite photodiode, the green perovskite photodiode, the red perovskite photodiode, and the infrared perovskite photodiode may include separate, respective portions of the first perovskite photoelectric conversion layer, and a cut-off wavelength of an absorption spectrum of the first Pb-free perovskite may belong to about 800 nm to about 3000 nm.

The image sensor may further include an infrared photodiode stacked with the first perovskite photodiode in a vertical direction perpendicular to an upper surface of the substrate.

The substrate may be a CMOS substrate, and the infrared photodiode may be a silicon photodiode integrated in the CMOS substrate.

The infrared photodiode may be a second perovskite photodiode stacked with the first perovskite photodiode on the substrate, and the second perovskite photodiode may include a third electrode, a fourth electrode, a second perovskite photoelectric conversion layer disposed between the third electrode and the fourth electrode and including a second Pb-free perovskite having a cut-off wavelength belonging to about 800 nm to about 3000 nm, and a second auxiliary layer between the third electrode and the second perovskite photoelectric conversion layer and including the organic compound represented by Chemical Formula 2.

According to some example embodiments, an electronic device including the image sensor is provided.

A photodiode and an image sensor capable of increasing wavelength selectivity and process selectivity and improving optical and electrical characteristics may be implemented with a simple structure.

### BRIEF DESCRIPTION OF THE DRAWINGS

FIG. 1 is a cross-sectional view showing a perovskite photodiode according to some example embodiments,

FIG. 2 is a cross-sectional view showing a perovskite photodiode according to some example embodiments,

FIG. 3 is a plan view illustrating an image sensor according to some example embodiments,

FIG. 4 is a cross-sectional view of the image sensor of FIG. 3 according to some example embodiments,

FIG. 5 is a plan view illustrating an image sensor according to some example embodiments,

FIG. 6 is a cross-sectional view of the image sensor of FIG. 5 according to some example embodiments,

FIG. 7 is a perspective view of an image sensor according to some example embodiments,

FIG. 8 is a cross-sectional view of the image sensor of FIG. 7 according to some example embodiments,

FIG. 9 is a cross-sectional view of the image sensor of FIG. 7 according to some example embodiments,

FIG. 10 is a schematic view of an electronic device according to some example embodiments,

FIG. 11 is a graph showing the external quantum efficiency (EQE) according to the wavelength of the photodiode according to Example 1,

FIG. 12 is a graph showing the external quantum efficiency (EQE) according to the wavelength of the photodiode according to Example 2,

FIG. 13 is a graph showing the dark currents of the photodiodes according to Example 1 and Comparative Example 1,

FIG. 14 is a graph showing the dark currents of the photodiodes according to Example 2 and Comparative Example 1,

FIG. 15 is a graph showing detectivity according to wavelength when a voltage of −0.5 V is applied to the photodiodes according to Example 1 and Comparative Example 1,

FIG. 16 is a graph showing detectivity according to wavelength when a voltage of −1.0 V is applied to the photodiodes according to Example 1 and Comparative Example 1,

FIG. 17 is a graph showing detectivity according to wavelength when a voltage of −0.5 V is applied to the photodiodes according to Example 2 and Comparative Example 1, and

FIG. 18 is a graph showing detectivity according to wavelength when a voltage of −1.0 V is applied to the photodiodes according to Example 2 and Comparative Example 1.

### DETAILED DESCRIPTION

Hereinafter, some example embodiments are described in detail so that those skilled in the art may easily implement them. However, the actual applied structure may be implemented in various different forms and is not limited to the example embodiments described herein.

In the drawings, the thickness of layers, films, panels, regions, etc., are exaggerated for clarity. It will be understood that when an element such as a layer, film, region, or substrate is referred to as being “on” another element, it may be directly on the other element or intervening elements may also be present. In contrast, when an element is referred to as being “directly on” another element, there are no intervening elements present.

In the drawings, parts having no relationship with the description are omitted for clarity, and the same or similar constituent elements are indicated by the same reference numeral throughout the specification.

Hereinafter, the terms “lower portion” and “upper portion” are for convenience of description and do not limit the positional relationship.

Hereinafter, the upper portion of the image sensor is described as a light-receiving side, but this is for convenience of description and does not limit the positional relationship.

Hereinafter, “combination” refers to a mixture or a stacked structure of two or more.

As used herein, “Cₓ-C_{y}” or “Cx to Cy” refers that a number (e.g., quantity) of carbons constituting a substituent is x to y, wherein x and y may each be any natural number. For example, “C₁-C₆” and “C1 to C6” means that a number of carbons constituting the substituent is 1 to 6, and “C₆-C₂₀” and C6 to C20” means that a number of carbons constituting the substituent is 6 to 20.

The term “alkyl group” as used herein refers to a linear or branched saturated aliphatic hydrocarbon monovalent group, and specific examples thereof include a methyl group, an ethyl group, a propyl group, an isobutyl group, a sec-butyl group, a ter-butyl group, a pentyl group, an iso-amyl group, a hexyl group, and the like. The term “alkylene group” as used herein refers to a linear or branched saturated aliphatic hydrocarbon divalent group, and specific examples thereof include a methylene group, an ethylene group, a propylene group, a butylene group, an isobutylene group, and the like.

The term “alkoxy group” as used herein refers to a monovalent group having a formula of −OA₁₀₁, wherein A₁₀₁ is an alkyl group. Specific examples thereof include a methoxy group, an ethoxy group, an isopropyloxy group, and the like.

The term “cycloalkyl group” as used herein refers to a monovalent saturated hydrocarbon cyclic group, and specific examples thereof include monocyclic groups such as a cyclopropyl group, a cyclobutyl group, a cyclopentyl group, a cyclohexyl group, a cycloheptyl group, and the like, and polycyclic condensed cyclic groups such as a norbornyl group, and an adamantyl group. The term “cycloalkylene group” as used herein refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

The term “heterocycloalkyl group” as used herein refers to a group having one or more carbon atoms in the cycloalkyl groups replaced by heteroatoms, for example, moieties containing oxygen, sulfur, or nitrogen. Heterocycloalkyl groups may contain, in particular, an ether bond, an ester bond, a sulfonic acid ester bond, a carbonate, a lactone ring, a sultone ring, or a carboxylic acid anhydrous moiety. The term “heterocycloalkylene group” as used herein refers to a group having one or more carbon atoms in the cycloalkylene groups replaced by moieties containing oxygen, sulfur, or nitrogen, for example.

The term “alkenyl” as used herein as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including at least one carbon-carbon double bond.

The term “cycloalkenyl group” as used herein refers to a monovalent unsaturated hydrocarbon cyclic group including one or more carbon-carbon double bonds.

The term “alkynyl group” as used herein refers to a linear or branched unsaturated aliphatic hydrocarbon monovalent group including one or more carbon-carbon triple bonds.

The term “aryl group” as used herein refers to a monovalent group having a carbocyclic aromatic system, and specific examples thereof include a phenyl group, a naphthyl group, an anthracenyl group, a phenanthrenyl group, a pyrenyl group, a chrysenyl group, and the like.

As used herein, when a definition is not otherwise provided, “substituted” refers to replacement of hydrogen of a compound by a substituent selected from a halogen, a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heterocyclic group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and any combination thereof.

Hereinafter, when a definition is not otherwise provided, “hetero” refers to inclusion of one or four heteroatoms selected from N, O, S, Se, Te, Si, and P.

Hereinafter, when a definition is not otherwise provided, the energy level is the highest occupied molecular orbital (HOMO) energy level or the lowest unoccupied molecular orbital (LUMO) energy level.

Hereinafter, when a definition is not otherwise provided, a work function or energy level is expressed as an absolute value from a vacuum level. Also, a deep, high or large work function or energy level means that the absolute values are large with reference to a vacuum level of “0 eV” and shallow, low or small work function or energy level means that the absolute values are small with reference to a vacuum level of “0 eV.”

Further, the differences between the work function and/or the energy level may be values obtained by subtracting a small value of the absolute value from a large value of the absolute value.

Hereinafter, when a definition is not otherwise provided, the HOMO energy level may be evaluated with an amount of photoelectrons emitted by energy when irradiating UV light to a thin film using AC-2 (Hitachi) or AC-3 (Riken Keiki Co., Ltd.).

Hereinafter, when a definition is not otherwise provided, the LUMO energy level may be obtained by obtaining an energy bandgap using a UV-Vis spectrometer (Shimadzu Corporation), and then calculating the LUMO energy level from the energy bandgap and the already measured HOMO energy level.

It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof. Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%, ±5%, ±3%, or ±1%). Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%, ±5%, ±3%, or ±1%). Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%, ±5%, ±3%, or ±1%). It will be understood that elements and/or properties thereof may be recited herein as being “identical” to, “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%, ±5%, ±3%, or ±1%) around the stated elements and/or properties thereof. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%, ±5%, ±3%, or ±1%). When the terms “about” or “substantially” are used in this specification in connection with a numerical value, it is intended that the associated numerical value includes a manufacturing or operational tolerance (e.g., ±10%, ±5%, ±3%, or ±1%) around the stated numerical value. Moreover, when the words “about” and “substantially” are used in connection with geometric shapes, it is intended that precision of the geometric shape is not required but that latitude for the shape is within the scope of the inventive concepts. Further, regardless of whether numerical values or shapes are modified as “about” or “substantially,” it will be understood that these values and shapes should be construed as including a manufacturing or operational tolerance (e.g., ±10%, ±5%, ±3%, or ±1%) around the stated numerical values or shapes. When ranges are specified, the range includes all values therebetween such as increments of 0.1%. As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other. As described herein, the terms “contact” and “direct contact” may be used interchangeably.

Hereinafter, a perovskite photodiode according to some example embodiments will be described.

A perovskite photodiode according to some example embodiments is a light absorption sensor capable of receiving light and converting it into an electrical signal, and may include perovskite as a photoelectric conversion material.

Hereinafter, a perovskite photodiode using perovskite will be described, but perovskite may also be applied to thin film transistors of various electronic devices and, for example, may be used as a perovskite active layer in thin film transistors.

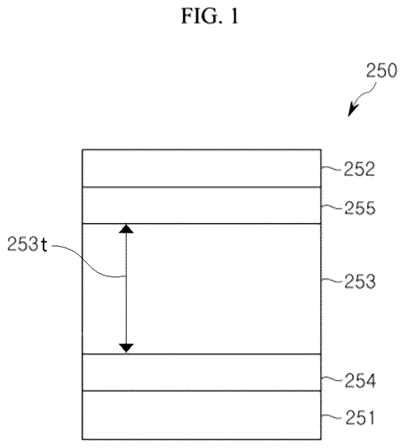

FIG. 1 is a cross-sectional view of a perovskite photodiode according to some example embodiments.

Referring to FIG. 1, a perovskite photodiode 250 according to some example embodiments includes a first electrode 251, a second electrode 252, a perovskite photoelectric conversion layer 253, a lower auxiliary layer 254, and an upper auxiliary layer 255.

A substrate (not shown) may be under the first electrode 251 or on the second electrode 252. The substrate may be, for example, an inorganic substrate such as a glass plate or a silicon wafer, or an organic substrate made of a polymer such as polycarbonate, polymethylmethacrylate, polyethyleneterephthalate, polyethylenenaphthalate, polyamide, polyethersulfone, or any combination thereof. The substrate may be omitted.

The substrate may be, for example, a semiconductor substrate or a silicon substrate. The semiconductor substrate may include a circuit unit (not shown), and the circuit unit may include transfer transistors (not shown) and/or charge storage (not shown) integrated in the semiconductor substrate. The circuit unit may be electrically connected to the first electrode 251 or the second electrode 252.

One of the first electrode 251 or the second electrode 252 may be an anode and the other may be a cathode. For example, the first electrode 251 may be an anode and the second electrode 252 may be a cathode. For example, the first electrode 251 may be a cathode and the second electrode 252 may be an anode.

At least one of the first electrode 251 or the second electrode 252 may be a light transmitting electrode. The light transmitting electrode may be a transparent electrode or a transflective electrode. The transparent electrode may have a transmittance of greater than or equal to about 85%, greater than or equal to about 90%, greater than or equal to about 95%, about 85% to about 100%, about 90% to about 100%, or about 95% to about 100%, and the transflective electrode may have a light transmittance of about 30% to about 85%, about 40% to about 80%, or about 40% to about 75%. The transparent electrode and the transflective electrode may include, for example, at least one of an oxide conductor, a carbon conductor, or a metal thin film. The oxide conductor may include for example at least one of indium tin oxide (ITO), indium zinc oxide (IZO), zinc tin oxide (ZTO), aluminum tin oxide (ATO), and aluminum zinc oxide (AZO), the carbon conductor may include at least one of graphene or carbon nanostructure, and the metal thin film may be a very thin film including aluminum (Al), magnesium (Mg), silver (Ag), gold (Au), magnesium-silver (Mg—Ag), magnesium-aluminum (Mg-AI), an alloy thereof, or any combination thereof.

One of the first electrode 251 or the second electrode 252 may be a reflective electrode. The reflective electrode may include a reflective layer having a light transmittance of less than or equal to about 5% and/or a reflectance of greater than or equal to about 80%, and the reflective layer may include an optically opaque material. The optically opaque material may include a metal, a metal nitride, or any combination thereof, for example silver (Ag), copper (Cu), aluminum (Al), gold (Au), titanium (Ti), chromium (Cr), nickel (Ni), an alloy thereof, a nitride thereof (e.g., TiN), or any combination thereof, but is not limited thereto. The reflective electrode may be formed of a reflective layer or may have a reflective layer/light transmitting layer or a stacked structure of a light transmitting layer/reflective layer/light transmitting layer, and the reflective layer may have one layer or two or more layers.

For example, each of the first electrode 251 and the second electrode 252 may be a light transmitting electrode, and either one of the first electrode 251 or the second electrode 252 may be a light-receiving electrode on a light receiving side.

For example, the first electrode 251 may be a light transmitting electrode, the second electrode 252 may be a reflective electrode, and the first electrode 251 may be a light-receiving electrode.

For example, the first electrode 251 may be a reflective electrode, and the second electrode 252 may be a light transmitting electrode and the second electrode 252 may be a light-receiving electrode.

The perovskite photoelectric conversion layer 253 may include perovskite and may be configured to convert light absorbed by the perovskite into an electrical signal. The perovskite may be an inorganic or organic-inorganic light absorbing material having a particular (or, alternatively, predetermined) crystal structure, and the perovskite may be a Pb-free perovskite that does not contain lead Pb (e.g., a Pb-free perovskite that does not contain any lead Pb). The Pb-free perovskite is environmentally friendly and may be effectively applied to semiconductor processes because it does not have the harmful effects of lead (Pb). Herein, when a perovskite is referred to, it will be understood that the perovskite may be a Pb-free perovskite, for example a Pb-free perovskite that does not contain any lead Pb.

For example, the Pb-free perovskite may be a metal halide perovskite including metal cations and halide anions. For example, the Pb-free perovskite may be an organic-inorganic metal halide perovskite including an organic cation, a metal cation, and a halide anion. For example, the Pb-free perovskite may be an organic-inorganic tin halide perovskite including tin ions (Sn²⁺) as metal cations.

The Pb-free perovskite may include, for example, organic-inorganic tin halide perovskite represented by Chemical Formula 1.

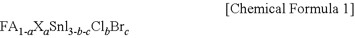

In Chemical Formula 1,
FA is formamidinium,
X is a substituted or unsubstituted methyl ammonium, a substituted or unsubstituted ethylene diammonium, a substituted or unsubstituted C6 to C12 aromatic alkylammonium, a substituted or unsubstituted C1 to C10 aliphatic ammonium, Cs⁺, Rb⁺, K⁺, Na⁺, or any combination thereof,

$$0 \leq a \leq 1 , 0 \leq b \leq 1 , and 0 \leq c \leq 1 ,$$

and
provided that, at least one of b or c is not 0.

For example, in Chemical Formula 1, X may be ethylene diammonium (EDA), methyl ammonium (MA), n-butyl ammonium (n-BA), fluorine-substituted phenethylammonium (F-PEA), Cs⁺, Rb⁺, K⁺, Na⁺, or any combination thereof.

For example, in Chemical Formula 1, a, b, and c may satisfy 0<a≤0.5, 0≤b≤0.5, 0≤c≤0.5 and 0<(b+c)≤0.5. For example, either b or c may be 0.

For example, the Pb-free perovskite may include FA₁₋ₐMAₐSnI_{3-b-c}Cl_{b}Br_{c}, FA₁₋ₐEDAₐSnI_{3-b-c}Cl_{b}Br_{c}, FA₁₋ₐ(F-PEA)ₐSnI_{3-b-c}Cl_{b}Br_{c}, FA₁₋ₐ₁₋ₐ₂(MA)ₐ₁(EDA)ₐ₂SnI_{3-b-c}Cl_{b}Br_{c}, FA₁₋ₐ₁₋ₐ₂(MA)ₐ₁(Cs)ₐ₂SnI_{3-b-c}Cl_{b}Br_{c}, FA₁₋ₐ₁₋ₐ₂(EDA)ₐ₁(Cs)ₐ₂SnI_{3-b-c}Cl_{b}Br_{c}, FA₁₋ₐ₁₋ₐ₂(F-PEA)ₐ₁(Cs)ₐ₂SnI_{3-b-c}Cl_{b}Br_{c}, FA₁₋ₐ₁₋ₐ₂(MA)ₐ₁(EDA)ₐ₂SnI_{3-b-c}Cl_{b}Br_{c}, FA₁₋ₐ₁₋ₐ₂(F-PEA)ₐ₁(EDA)ₐ₂SnI_{3-b-c}Cl_{b}Br_{c}, FA₁₋ₐ₁₋ₐ₂(F-PEA)ₐ₁(MA)ₐ₂SnI_{3-b-c}Cl_{b}Br_{c}, or any combination thereof. Herein, FA is formamidinium, MA is methyl ammonium, EDA is ethylene diammonium, F-PEA is fluorine-substituted phenethylammonium, (a1+a2)=a may be satisfied, and 0<a≤0.5, 0<(a1+a2)≤0.5, 0≤a1≤0.5, 0≤a2≤0.5, 0≤b≤0.5, 0≤c≤0.5 and 0<(b+c)≤0.5 may be satisfied. While as noted above, (a1+a2)=a may be satisfied, it will be understood that example embodiments are not limited thereto. For example, in some example embodiments, (a1+a2)≠a.

The perovskite may be configured to absorb light of at least a portion of the visible to infrared wavelength spectra. Herein, the visible wavelength spectrum may be for example greater than or equal to about 380 nm and less than about 750 nm, within the above range, about 380 nm to about 730 nm, about 380 nm to about 720 nm, about 380 nm to about 710 nm, about 380 nm to about 700 nm, about 380 nm to about 680 nm, about 380 nm to about 650 nm, greater than or equal to about 400 nm and less than about 750 nm, about 400 nm to about 730 nm, about 400 nm to about 720 nm, about 400 nm to about 710 nm, about 400 nm to about 700 nm, about 400 nm to about 680 nm, or about 400 nm to about 650 nm. Herein, the infrared wavelength spectrum may include a portion or all of the near-infrared, short-wave infrared, mid-wave infrared, and far-infrared wavelength spectrum, for example greater than about 750 nm and less than or equal to about 3000 nm, within the above range, greater than about 750 nm and less than or equal to about 2500 nm, greater than about 750 nm and less than or equal to about 2000 nm, greater than about 750 nm and less than or equal to about 1800 nm, greater than about 750 nm and less than or equal to about 1500 nm, about 800 nm to about 3000 nm, about 800 nm to about 2500 nm, about 800 nm to about 2000 nm, about 800 nm to about 1800 nm, or about 800 nm to about 1500 nm, but is not limited thereto.

For example, the absorption spectrum of perovskite may have a relatively high absorbance over a wavelength spectrum from a short wavelength (for example, a wavelength belonging to an X-ray or UV-ray region) to a visible wavelength spectrum. The absorption characteristics of perovskite may be represented by the cut-off wavelength of the absorption spectrum, and the cut-off wavelength of the absorption spectrum may be an end of the absorption spectrum, that is, the long-wavelength endpoint (e.g., long-wavelength endpoint wavelength) of the wavelength spectrum that the perovskite may be configured to absorb. The cut-off wavelength of the absorption spectrum of the perovskite may be determined by (e.g., may be based on) an energy bandgap of the perovskite, and the perovskite may have an energy bandgap that matches the visible wavelength spectrum. For example, the energy bandgap of the perovskite may be about 1.1 eV to about 3.0 eV, within the above range, about 1.1 eV to about 2.8 eV or about 1.2 eV to about 2.5 eV.

For example, the absorption spectrum of the perovskite may include all of the visible wavelength spectrum, the cut-off wavelength of the perovskite may exist at the endpoint (e.g., long-wavelength endpoint wavelength) of the visible wavelength spectrum or at a longer wavelength point, and for example the cut-off wavelength of the perovskite may belong to a wavelength spectrum of about 700 nm to about 3000 nm.

As an example, the cut-off wavelength of the absorption spectrum of the perovskite may be a boundary point (e.g., boundary wavelength) between the visible wavelength spectrum and the infrared wavelength spectrum, and for example, may be greater than about 650 nm and less than about 750 nm, within the above range, about 670 nm to about 730 nm, about 680 nm to about 720 nm, or about 690 nm to about 710 nm.

For example, the absorption spectrum of the perovskite may have a relatively high absorbance from a short wavelength (e.g., a wavelength belonging to an X-ray or UV-ray region) to an infrared wavelength spectrum. The perovskite may have an energy bandgap that matches the infrared wavelength spectrum.

For example, the cut-off wavelength of the absorption spectrum of the perovskite may be the endpoint of the infrared wavelength spectrum to be photoelectrically converted, and may be a longer wavelength than the cut-off wavelength of the absorption spectrum of a perovskite configured to absorb the visible wavelength spectrum.

For example, the cut-off wavelength of the absorption spectrum of the perovskite configured to absorb light in the infrared wavelength spectrum may belong to, for example, about 800 nm to about 3000 nm, and within the above range, about 800 nm to about 2500 nm, about 800 nm to about 2200 nm, about 800 nm to about 2000 nm, about 800 nm to about 1800 nm, about 800 nm to about 1500 nm, about 800 nm to about 1300 nm, about 900 nm to about 2500 nm, about 900 nm to about 2200 nm, about 900 nm to about 2000 nm, about 900 nm to about 1800 nm, about 900 nm to about 1500 nm, about 900 nm to about 1300 nm, about 1000 nm to about 2500 nm, about 1000 nm to about 2200 nm, about 1000 nm to about 2000 nm, about 1000 nm to about 1800 nm, about 1000 nm to about 1500 nm, or about 1000 nm to about 1300 nm.

The perovskite photoelectric conversion layer 253 may include one or two or more types of perovskites in order to have such light absorption characteristics, and may include two or more types of perovskites represented by Chemical Formula 1 (e.g., two or more different perovskites that are each independently represented by Chemical Formula 1) and/or may further include perovskite structures other than the perovskite represented by Chemical Formula 1.

The perovskite may have wavelength selectivity as the cut-off wavelength of the absorption spectrum may be determined according to (e.g., may be based on) the energy bandgap as described above. Accordingly, unlike silicon configured to uniformly absorb light of a broad wavelength spectrum from a short wavelength (around 200 nm) to an infrared wavelength spectrum without wavelength selectivity, the perovskite photoelectric conversion layer 253 may exclude light of the infrared wavelength spectrum (e.g., may not absorb any or substantially any light of the infrared wavelength spectrum) and the perovskite photoelectric conversion layer 253 may absorb light of the visible wavelength spectrum, even without receiving light through a separate infrared blocking filter (e.g., even without the incident light on the perovskite photoelectric conversion layer 253 having already been at least partially filtered of infrared light). As a result, a perovskite photodiode 250, and an image sensor including same, may have improved wavelength selectivity in comparison to silicon photodiodes and image sensors including same with regard to absorbing light excluding light of the infrared wavelength spectrum, including having such improved wavelength selectively without including a separate infrared filter to filter infrared light from the light that is incident on the perovskite photodiode 250. As a result, a perovskite photodiode 250, and an image sensor including same may have improved photoelectric conversion performance and/or efficiency, improved wavelength selectively, and/or improved compactness and miniaturization (e.g., based on omitting a separate infrared filter) without compromising photoelectric conversion performance, photoelectric conversion efficiency, and/or wavelength selectively.

In addition, since the perovskite may have an absorbance of about 10 times or more (e.g., about 10 times to about 1000 times) compared to silicon, the perovskite photodiode 250 may have a higher absorption characteristic than a conventional silicon photodiode. For example, the thickness 253t of the perovskite photoelectric conversion layer 253 for absorbing the same amount of light may be reduced to about 1/10 or less than the thickness of a conventional silicon photodiode configured to absorb the same amount (e.g., intensity) of light. The perovskite photoelectric conversion layer 253 may have a relatively thinner thickness 253t (e.g., in comparison to a silicon photodiode configured to absorb a same or substantially same amount of light in the visible wavelength spectrum) due to such high light absorption characteristics, for example, about 100 nm to about 800 nm, about 100 nm to about 700 nm, about 100 nm to about 500 nm, or about 200 nm to about 500 nm. Accordingly, the perovskite photodiode 250 may have reduced size, and thus improved compactness and/or miniaturization, in comparison to a silicon-based photodiode, without compromising light absorbing and photoelectric conversion performance and/or light absorbing and photoelectric conversion efficiency. Accordingly, an image sensor including a perovskite photodiode 250 may have reduced size, and thus improved compactness and/or miniaturization, in comparison to an image sensor including a silicon-based photodiode, where the improved compactness and miniaturization is achieved without compromising light absorbing and photoelectric conversion performance and/or light absorbing and photoelectric conversion efficiency.

In addition, since the perovskite has a charge mobility of about 1000 times or more (for example, about 1000 times to about 10⁶ times) higher than organic photoelectric conversion materials, the perovskite may have higher photoelectric conversion efficiency and lower remaining charges in relation to the organic photoelectric conversion materials in addition to having higher light absorption characteristics in relation to the organic photoelectric conversion materials. As a result, a perovskite photodiode 250, and an image sensor including same may have improved photoelectric conversion performance and/or efficiency.

In addition, the perovskite may be applied to both solution processes such as spin coating, slit coating, and inkjet coating, and deposition processes such as vacuum deposition and thermal deposition, and thus process selectivity may be broadened and it may be applied to semiconductor processes requiring fine patterning effectively. As a result, manufacturing costs and/or complexity to manufacture a perovskite photodiode 250 and/or an image sensor including same may be reduced or minimized. Reduced manufacturing complexity may reduce a likelihood of process defects in the manufactured devices, thereby improving reliability of manufactured devices. Accordingly, manufacturing costs and/or complexity for processes to manufacture an image sensor may be reduced, and/or the reliability of the image sensor may be improved, based on the image sensor including a perovskite photodiode 250.

The lower auxiliary layer 254 is between the first electrode 251 and the perovskite photoelectric conversion layer 253. For example, the lower auxiliary layer 254 may be in contact with the perovskite photoelectric conversion layer 253, and for example, one surface of the lower auxiliary layer 254 may be in contact with the perovskite photoelectric conversion layer 253, and the other, opposite surface of the lower auxiliary layer 254 may be in contact with the first electrode 251.

The lower auxiliary layer 254 may be an organic layer including organic single molecules, for example, an organic layer including depositable organic single molecules.

For example, the lower auxiliary layer 254 may include an organic compound having an asymmetric core including different fused rings, and the organic compound may be for example represented by Chemical Formula 2.

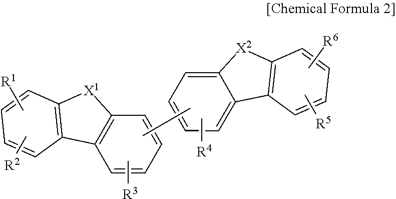

In Chemical Formula 2,
X¹ and X² are different from each other, and X¹ and X² are each independently one of CR^{a}R^{b}, SiR^{c}R^{d}, or NR^{e},
R¹ to R⁶ are each independently hydrogen, a substituted or unsubstituted C1 to C30 alkyl group, a substituted or unsubstituted C1 to C30 alkoxy group, a substituted or unsubstituted C6 to C20 aryl group, a substituted or unsubstituted C3 to C20 heterocyclic group, a halogen, a cyano group, —NR^{f}R^{g}, or any combination thereof,
at least one of R¹ or R⁶ is a substituted or unsubstituted C6 to C20 aryl group, a substituted or unsubstituted C3 to C20 heterocyclic group, —NR^{f}R^{g}, or any combination thereof,
R^{a} to R^{g} are each independently hydrogen, a substituted or unsubstituted C1 to C30 alkyl group, a substituted or unsubstituted C6 to C20 aryl group, a substituted or unsubstituted C3 to C20 heterocyclic group, a halogen, a cyano group, or any combination thereof,
R^{a} and R^{b} are each independently present or are combined with each other to form a ring (e.g., a first ring),
R^{c} and R^{d} are each independently present or are combined with each other to form a ring (e.g., a second ring), and
R^{f} and R^{g} are each independently present or are combined with each other to form a ring (e.g., a third ring).

For example, in Chemical Formula 2, X¹ may be CR^{a}R^{b} or SiR^{c}R^{d}, and X² may be NR^{e}. For example, R^{a} to R^{d} may independently be hydrogen, a substituted or unsubstituted C1 to C30 alkyl group or a substituted or unsubstituted C6 to C20 aryl group, and for example R^{a} to R^{d} may independently be hydrogen, a substituted or unsubstituted methyl group, a substituted or unsubstituted ethyl group, a substituted or unsubstituted propyl group, a substituted or unsubstituted butyl group, a substituted or unsubstituted pentyl group, a substituted or unsubstituted hexyl group, a substituted or unsubstituted heptyl group, a substituted or unsubstituted octyl group, a substituted or unsubstituted phenyl group, a substituted or unsubstituted biphenyl group, a substituted or unsubstituted naphthyl group, a substituted or unsubstituted anthracenyl group, a substituted or unsubstituted phenanthryl group, or any combination thereof. For example, R^{e} may be a substituted or unsubstituted C6 to C20 aryl group, for example a substituted or unsubstituted phenyl group, a substituted or unsubstituted biphenyl group, a substituted or unsubstituted naphthyl group, a substituted or unsubstituted anthracenyl group, a substituted or unsubstituted phenanthryl group, or any combination thereof.

For example, in Chemical Formula 2, X¹ may be CR^{a}R^{b} and X² may be NR^{e}.

For example, at least one of R¹ or R⁶ may be —NR^{f}R^{g}, and for example, R¹ and R⁶ may each be —NR^{f}R^{g}. For example, R^{f} and R^{g} may combine to form a ring, and may be for example bonded to form the ring through a single bond, a substituted or unsubstituted C1 to C5 alkylene group, a substituted or unsubstituted C2 to C5 alkenylene group, a substituted or unsubstituted C6 to C20 arylene group, O, S, Se, Te, CR^{h}Rⁱ, SiR^{j}R^{k}, or GeR^{l}R^{m}. R^{h} to R^{m} may each independently be hydrogen, a substituted or unsubstituted C1 to C30 alkyl group, a substituted or unsubstituted C6 to C20 aryl group, a substituted or unsubstituted C3 to C20 heterocyclic group, a halogen, a cyano group, or any combination thereof.

For example, at least one of R¹ or R⁶ may be one of groups listed in Group 1, and for example, R¹ and R⁶ may each be one group of the plurality of groups listed in Group 1.

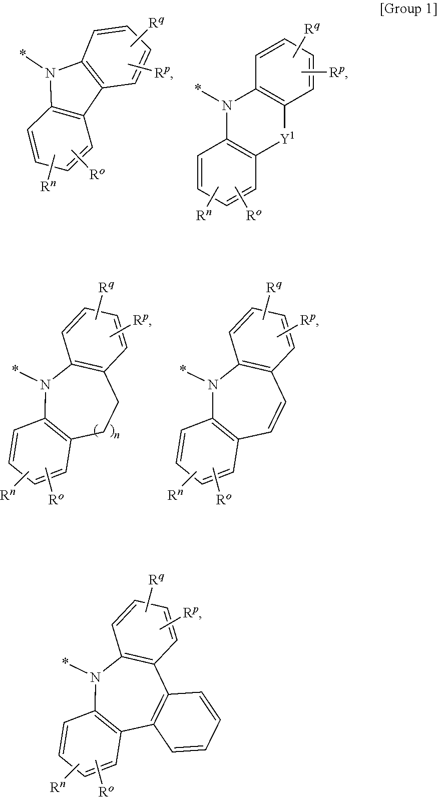

In Group 1,
Y¹ may be O, S, Se, Te, CR^{h}Rⁱ, SiR^{j}R^{k}, or GeR^{l}R^{m},
R^{h} to R^{q} may independently be hydrogen, a substituted or unsubstituted C1 to C30 alkyl group, a substituted or unsubstituted C6 to C20 aryl group, a substituted or unsubstituted C3 to C20 heterocyclic group, a halogen, a cyano group, or any combination thereof,
n may be an integer of 0 to 2, and
* may be a linking point with Chemical Formula 2.

For example, R² to R⁵ may independently be hydrogen, a substituted or unsubstituted C1 to C30 alkyl group, a halogen, a cyano group, or any combination thereof, and for example, R² to R⁵ may independently be hydrogen.

For example, the organic compound represented by Chemical Formula 2 may be represented by Chemical Formula 2A.

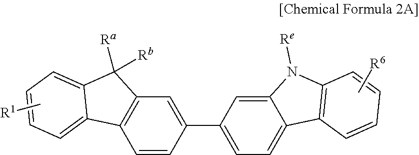

In Chemical Formula 2A, R^{a}, R^{b}, R^{e}, R¹, and R⁶ are the same as R^{a}, R^{b}, R^{e}, R¹, and R⁶ as described above with reference to Chemical Formula 2. For example, in Chemical Formula 2A R^{a} and R^{b} may each independently be hydrogen, a substituted or unsubstituted C1 to C30 alkyl group or a substituted or unsubstituted C6 to C20 aryl group, R^{e} may be a substituted or unsubstituted C6 to C20 aryl group, and R¹ and R⁶ may each independently be one group of the plurality of groups listed in Group 1.

For example, the organic compound represented by Chemical Formula 2A may be represented by Chemical Formula 2AA.

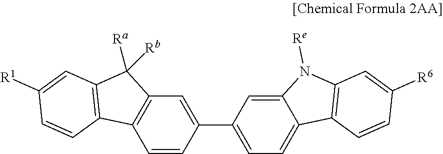

In Chemical Formula 2AA, R^{a}, R^{b}, R^{e}, R¹, and R⁶ are the same as R^{a}, R^{b}, R^{e}, R¹, and R⁶ as described above with reference to Chemical Formula 2. For example, in Chemical Formula 2A R^{a} and R^{b} may each independently be hydrogen, a substituted or unsubstituted C1 to C30 alkyl group or a substituted or unsubstituted C6 to C20 aryl group, R^{e} may be a substituted or unsubstituted C6 to C20 aryl group, and R¹ and R⁶ may each independently be one group of the plurality of groups listed in Group 1.

The organic compound may be a depositable organic semiconductor that has high heat resistance and satisfies a particular (or, alternatively, predetermined) energy level, and may be effectively applied as an auxiliary layer of a perovskite photodiode due to such characteristics.

For example, the organic compound may have a relatively high glass transition temperature due to an asymmetric core structure, and for example, the glass transition temperature of the organic compound may be greater than or equal to about 170° C., greater than or equal to about 180° C., greater than or equal to about 190° C., greater than or equal to about 195° C., greater than or equal to about 200° C., or greater than or equal to about 210° C., within the above range, about 170° C. to about 400° C., about 180° C. to about 400° C., about 190° C. to about 400° C., about 195° C. to about 400° C., about 200° C. to about 400° C., or about 210° C. to about 400° C. Accordingly, the lower auxiliary layer 254 including the organic compound may have high heat resistance that is not easily deteriorated in a subsequent process.

For example, the organic compound may be sublimated without decomposition or polymerization within a particular (or alternatively, predetermined) temperature range. For example, the temperature (Ts₁₀) at which a weight loss of 10% compared to the initial weight occurs during thermogravimetric analysis at a pressure of about 1 Pa or less (e.g., about 0.01 Pa to about 1 Pa, about 0.1 Pa to about 1 Pa, about 0.2 Pa to about 1 Pa, or the like) may be about 180° C. to about 450° C., about 190° C. to about 450° C., about 200° C. to about 450° C., about 210° C. to about 450° C., or about 220° C. to about 450° C., and a temperature at which a weight loss of 50% compared to the initial weight (Ts₅₀) occurs may be about 200° C. to about 500° C., about 220° C. to about 500° C., or about 250° C. to about 500° C. By having such high heat resistance, the organic compound may be stably and repeatedly deposited and may maintain good performance without deterioration in subsequent high-temperature processes.

As described above, the organic compound may satisfy a particular (or alternatively, predetermined) energy level due to a structure having an asymmetric core. For example, a lowest unoccupied molecular orbital (LUMO) energy level of the organic compound may be less than or equal to about 2.80 eV, less than or equal to about 2.75 eV, less than or equal to about 2.70 eV, less than or equal to about 2.65 eV, or less than or equal to about 2.60 eV, within the above range, about 2.00 eV to about 2.80 eV, about 2.00 eV to about 2.75 eV, about 2.00 eV to about 2.70 eV, about 2.00 eV to about 2.65 eV, or about 2.00 eV to about 2.60 eV. For example, a highest occupied molecular orbital (HOMO) energy level of the organic compound may be less than or equal to about 5.70 eV, less than or equal to about 5.68 eV, or less than or equal to about 5.65 eV, within the above range, about 5.20 eV to about 5.70 eV, about 5.20 eV to about 5.68 eV, or about 5.20 eV to about 5.65 eV.

Since the organic compound has the energy levels, the lower auxiliary layer 254 may more effectively extract the first charges (e.g., holes) separated from the perovskite photoelectric conversion layer 253 toward the first electrode 251, and at the same time, when a voltage is applied from the outside (e.g., from external to the lower auxiliary layer 254 and/or the perovskite photodiode 250, reverse injection of second charges (e.g., electrons) from the first electrode 251 to the perovskite photoelectric conversion layer 253 may be more effectively blocked. Accordingly, electrical characteristics of the perovskite photodiode 250 may be improved by effectively reducing remaining charge and dark current while increasing photoelectric conversion efficiency of the perovskite photodiode 250, based on the perovskite photodiode 250. However, it will be understood that, in some example embodiments, one or both of the lower auxiliary layer 254 and/or the upper auxiliary layer 255 may be omitted from the perovskite photodiode 250, for example such that the perovskite photodiode 250 includes the perovskite photoelectric conversion layer 253 directly or indirectly connected between the first and second electrodes 251 and 252 and where one or both of the lower and upper auxiliary layers 254 and 255 are absent from the perovskite photodiode 250.

The upper auxiliary layer 255 is between the second electrode 252 and the perovskite photoelectric conversion layer 253. The upper auxiliary layer 255 may be a charge auxiliary layer that controls the mobility of charges (e.g., electrons) moving from the perovskite photoelectric conversion layer 253 and/or a light-absorption auxiliary layer that improves light absorption characteristics and may include one or two or more layers.

The upper auxiliary layer 255 may include organic, inorganic, and/or organic-inorganic materials, for example a metal halide such as LiF, NaCl, CsF, RbCl, and RbI; a lanthanide metal such as Yb; a metal such as calcium (Ca), potassium (K), aluminum (Al), or an alloy thereof; a metal oxide such as Li₂O and BaO; fullerenes such as C60, C70 or a derivative thereof; Liq (lithium quinolate), Alq3 (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, TPBi (1,3,5-tri(1-phenyl-1H-benzo[d]imidazol-2-yl)phenyl), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tertbutylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), Bebq₂ (berylliumbis(benzoquinolin-10-olate), ADN (9,10-di(naphthalene-2-yl)anthracene), BmPyPhB (1,3-bis[3,5-di(pyridin-3-yl)phenyl]benzene), or any combination thereof, but is not limited thereto.

As described herein, examples of a fullerene may include C60, C70, C76, C78, C80, C82, C84, C90, C96, C240, C540, a mixture thereof, a fullerene nanotube, and the like. A fullerene derivative may refer to compounds of these fullerenes having a substituent thereof. The fullerene derivative may include a substituent such as an alkyl group (e.g., C1 to C30 alkyl group), an aryl group (e.g., C6 to C30 aryl group), a heterocyclic group (e.g., C3 to C30 heterocycloalkyl group), and the like. Examples of the aryl groups and heterocyclic groups may be a benzene ring, a naphthalene ring, an anthracene ring, a phenanthrene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, a isobenzofuran ring, a benzimidazole ring, a imidazopyridine ring, a quinolizidine ring, a quinoline ring, a phthalazine ring, a naphthyridine ring, a quinoxaline ring, an isoquinoline ring, a carbazole ring, a phenanthridine ring, an acridine ring, a phenanthroline ring, a thianthrene ring, a chromene ring, an xanthene ring, a phenoxazine ring, a phenoxathiin ring, a phenothiazine ring, or a phenazine ring.

The upper auxiliary layer 255 may be omitted.

The perovskite photodiode 250 may further include an anti-reflection layer (not shown) under the first electrode 251 or on (e.g., above) the second electrode 252. For example, when the first electrode 251 is a light-receiving electrode, the anti-reflection layer may be positioned below the first electrode 251. For example, when the second electrode 252 is a light-receiving electrode, the anti-reflection layer may be on the second electrode 252. The anti-reflection layer may further improve light absorption by lowering reflectance of incident light by being disposed at a side where light is incident. The anti-reflection layer may include, for example, a material having a refractive index of about 1.6 to about 2.5, and may include, for example, at least one of a metal oxide, a metal sulfide, or an organic material having a refractive index within the above range. The anti-reflection layer may include, for example a metal oxide such as aluminum-containing oxide, molybdenum-containing oxide, tungsten-containing oxide, vanadium-containing oxide, rhenium-containing oxide, niobium-containing oxide, tantalum-containing oxide, titanium-containing oxide, nickel-containing oxide, copper-containing oxide, cobalt-containing oxide, manganese-containing oxide, chromium-containing oxide, tellurium-containing oxide, or any combination thereof; a metal sulfide such as zinc sulfide; or an organic material such as an amine derivative, but is not limited thereto.

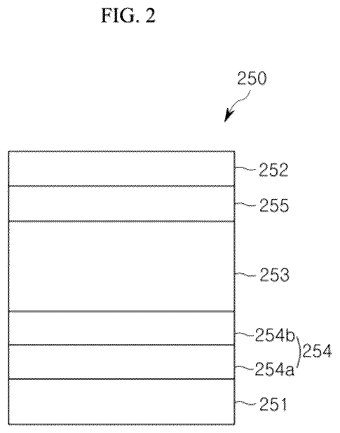

FIG. 2 is a cross-sectional view of a perovskite photodiode according to some example embodiments.

Referring to FIG. 2, the perovskite photodiode 250 according to some example embodiments includes a first electrode 251, a second electrode 252, and a perovskite photoelectric conversion layer 253, a lower auxiliary layer 254, and an upper auxiliary layer 255, as in some example embodiments, including the example embodiments shown in FIG. 1.

However, the perovskite photodiode 250 according to some example embodiments, including the example embodiments shown in FIG. 2, includes a two-layer lower auxiliary layer 254, unlike some example embodiments, including the example embodiments shown in FIG. 1. That is, the lower auxiliary layer 254 includes a first lower auxiliary layer 254a close to the first electrode 251 and a second lower auxiliary layer 254b close to the perovskite photoelectric conversion layer 253, for example such that the first lower auxiliary layer 254a is between the second lower auxiliary layer 254b and the first electrode, and the second lower auxiliary layer 254b is between the first lower auxiliary layer 254a and the perovskite photoelectric conversion layer 253. Any one of the first lower auxiliary layer 254a or the second lower auxiliary layer 254b may include the compound represented by Chemical Formula 1, and the other one of the first lower auxiliary layer 254a or the second lower auxiliary layer 254b may include a material having charge transport characteristics other than the aforementioned compounds (e.g., charge transport characteristics other than that of the compound represented by Chemical Formula 1 that is included in the one of the first lower auxiliary layer 254a or the second lower auxiliary layer 254b). For example, the first lower auxiliary layer 254a may include the compound represented by Chemical Formula 1, and the second lower auxiliary layer 254b may include a material having charge transport characteristics other than the aforementioned compounds (e.g., other than the compound represented by Chemical Formula 1 that is included in the first lower auxiliary layer 254a).

The material having charge transport characteristics other than the aforementioned compounds may include a phthalocyanine compound such as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino]triphenylamine), TDATA (4,4′4″-tris(N,N-diphenylamino)triphenylamine), 2-TNATA (4,4′,4″-tris{N,N-(2-naphthyl)-N-phenylamino}-triphenylamine), PEDOT/PSS (poly(3,4-ethylenedioxythiophene)/poly(4-styrenesulfonate)), PANI/DBSA (polyaniline/dodecylbenzenesulfonic acid), PANI/CSA (polyaniline/Camphor sulfonic acid), PANI/PSS (polyaniline/poly(4-styrenesulfonate)), NPB (N,N′-di(naphthalene-1-yl)-N,N′-diphenylbenzidine), polyetherketone including triphenylamine (TPAPEK), 4-isopropyl-4′-methyldiphenyliodonium[tetrakis(pentafluorophenyl)borate], HAT-CN (dipyrazino[2,3-f: 2′,3′-h]quinoxaline-2,3,6,7,10,11-hexacarbonitrile), a carbazole-based derivative such as N-phenylcarbazole, polyvinylcarbazole, and the like, a fluorene-based derivative, TPD (N,N′-bis(3-methylphenyl)-N,N′-diphenyl-[1,1-biphenyl]-4,4′-diamine), a triphenylamine-based derivative such as TCTA (4,4′,4″-tris(N-carbazolyl)triphenylamine), NPB (N,N′-di(naphthalene-1-yl)-N,N′-diphenyl-benzidine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), mCP (1,3-bis(N-carbazolyl)benzene), or any combination thereof, but is not limited thereto.

As such, the perovskite photodiode 250 may include the lower auxiliary layer 254 of two layers, so that dark current and leakage current may be more effectively reduced while having equal or improved charge transportability, thereby improving the photoelectric conversion performance and/or efficiency of the perovskite photodiode 250 and any image sensor including same.

For example, the aforementioned perovskite photodiode 250 may be included in an image sensor, and may be applied to an image sensor suitable for high-speed imaging by having improved optical and electrical characteristics as described above.

Hereinafter, an image sensor according to some example embodiments is described.

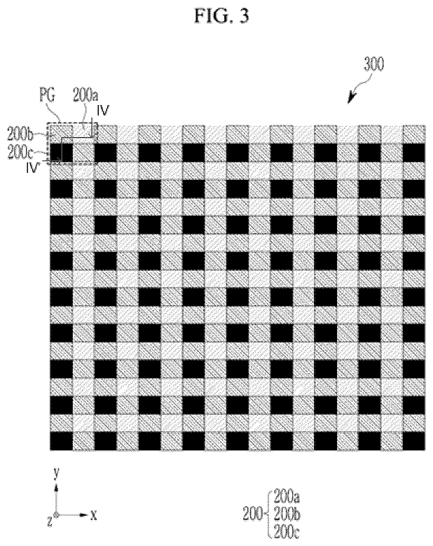

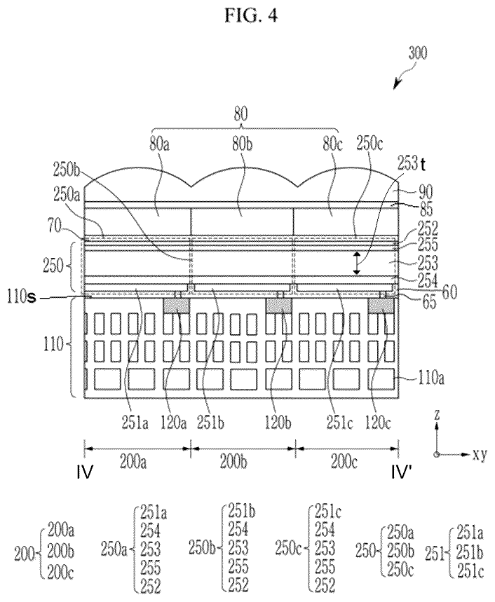

FIG. 3 is a plan view of an image sensor according to some example embodiments and FIG. 4 is a cross-sectional view of the image sensor of FIG. 3 according to some example embodiments. FIG. 4 may be a cross-sectional view along view line IV-IV′ in FIG. 3.

Referring to FIG. 3, the image sensor 300 includes a plurality of pixels 200 for absorbing light of different first, second, and third wavelength spectrums belonging to a visible wavelength spectrum and performing photoelectric conversion. The plurality of pixels 200 may include a blue pixel 200a configured to selectively sense light of a blue wavelength spectrum, a green pixel 200b configured to selectively sense light of a green wavelength spectrum, and a red pixel 200c configured to selectively sense light of a red wavelength spectrum, and each pixel 200 may be a blue pixel 200a, a green pixel 200b, or a red pixel 200c. The image sensor 300 may obtain a particular (or, alternatively, predetermined) image based on combining electrical signals obtained from (e.g., generated by) the blue pixel 200a, the green pixel 200b, and the red pixel 200c. At least one blue pixel 200a, at least one green pixel 200b, and at least one red pixel 200c may form (e.g., define) one pixel group PG and may be repeatedly arranged along rows and/or columns. Each pixel group PG may include, for example, one blue pixel 200a, two green pixels 200b, and one red pixel 200c, but is not limited thereto.

Referring to FIG. 4, the image sensor 300 includes a substrate 110, a first perovskite photodiode 250 (also referred to herein interchangeably as a perovskite photodiode), a wavelength selective filter layer 80, insulating layers 60 and 70, and a focusing lens 90.

The substrate 110 may be a semiconductor substrate, for example, a silicon substrate. The substrate 110 may be, for example, a CMOS substrate and may include a CMOS circuit unit 110a. The substrate 110 may include charge storages 120a, 120b, and 120c and a transmission transistor (not shown). The charge storages 120a, 120b, and 120c are electrically connected to the perovskite photodiode 250 and the charge storages 120a, 120b, and 120c and the surface of the substrate 110 may be separated from the perovskite photodiode 250 by an insulating layer 60. The charge storages 120a, 120b, and 120c are electrically connected to the perovskite photodiode 250 via a conductive via 65 or pillar through the insulating layer 60, said conductive via 65 comprising a conductive material such as metal (e.g., copper) or a metal alloy. A metal wire (not shown) and a pad (not shown) may be formed under or on the substrate 110.

The perovskite photodiode 250 may be electrically separated for each pixel 200a, 200b, and 200c, and includes the blue perovskite photodiode 250a included in the blue pixel 200a, the green perovskite photodiode 250b included in the green pixel 200b, and the red perovskite photodiode 250c included in the red pixel 200c. The blue perovskite photodiode 250a, the green perovskite photodiode 250b, and the red perovskite photodiode 250c are arranged along (e.g., in parallel or substantially in parallel with) the in-plane direction (e.g., xy direction) of the substrate 110 to form a visible light diode array. The in-plane direction (e.g., the xy direction) may include one or more horizontal directions and/or a horizontal plane (e.g., an xy plane), where the one or more horizontal directions and/or the horizontal plane (e.g., an xy plane) extend parallel or substantially parallel to the upper surface 110s of the substrate 110. A vertical direction (e.g., z direction) may extend perpendicular or substantially perpendicular to the upper surface 110s of the substrate 110 and may extend perpendicular to the one or more horizontal directions (e.g., the xy direction) and/or the horizontal plane (e.g., the xy plane).

The blue perovskite photodiode 250a, the green perovskite photodiode 250b, and the red perovskite photodiode 250c may respectively include first electrodes 251a, 251b, and 251c, separate, respective portions of the second electrode 252, separate, respective portions of the first perovskite photoelectric conversion layer 253 (also referred to herein interchangeably as the perovskite photoelectric conversion layer) between the first electrodes 251a, 251b, and 251c and the second electrode 252, separate, respective portions of a lower auxiliary layer 254 between the first electrodes 251a, 251b, and 251c and the first perovskite photoelectric conversion layer 253, and separate, respective portions of an upper auxiliary layer 255 between the second electrode 252 and the first perovskite photoelectric conversion layer 253, and descriptions of the first electrodes 251a, 251b, and 251c, the second electrode 252, the lower auxiliary layer 254, and the upper auxiliary layer 255 are the same as described above. The first perovskite photoelectric conversion layer 253 is the same as the aforementioned perovskite photoelectric conversion layer 253, and separate, respective portions of the first perovskite photoelectric conversion layer 253 are included in a blue perovskite photodiode 250a, a green perovskite photodiode 250b, and a red perovskite photodiode 250c in common. For example, the blue perovskite photodiode 250a, the green perovskite photodiode 250b, and the red perovskite photodiode 250c may each include a separate portion of the second electrode 252, a separate portion of the first perovskite photoelectric conversion layer 253, a separate portion of the lower auxiliary layer 254, and a separate portion of the upper auxiliary layer 255.

The first perovskite photoelectric conversion layer 253 may include the aforementioned perovskite, and the blue wavelength spectrum transmitted through the first, second, and third wavelength selective filters 80a, 80b, and 80c, respectively. of light (or light including the blue wavelength spectrum), light of the green wavelength spectrum (or light including the green wavelength spectrum), or light of the red wavelength spectrum (or light including the red wavelength spectrum) may be absorbed by the perovskite to convert light in the visible wavelength spectrum into an electrical signal.

The wavelength selective filter layer 80 may be configured to selectively transmit light of a particular (or, alternatively, predetermined) wavelength spectrum among incident visible wavelength spectrum light, and may be configured to absorb and/or reflect light of the remaining wavelength spectrum except for a particular (or, alternatively, predetermined) wavelength spectrum among the visible wavelength spectrum. The particular (or, alternatively, predetermined) wavelength spectrum may be a limited wavelength spectrum among the visible wavelength spectrum. The wavelength selective filter layer 80 may provide wavelength selectivity of the light to be photoelectrically converted, to the blue perovskite photodiode 250a, the green perovskite photodiode 250b, and the red perovskite photodiode 250c disposed thereunder.

The wavelength selective filter layer 80 includes a first wavelength selective filter 80a included in the blue pixel 200a, a second wavelength selective filter 80b included in the green pixel 200b, and a third wavelength selective filter 80c included in the red pixel 200c. The first wavelength selective filter 80a may be overlapped with the blue perovskite photodiode 250a in the blue pixel 200a (e.g., overlapped in a vertical direction perpendicular or substantially perpendicular to the upper surface 110s of the substrate 110) and may be on the blue perovskite photodiode 250a. The second wavelength selective filter 80b may be overlapped with the green perovskite photodiode 250b in the green pixel 200b (e.g., overlapped in a vertical direction perpendicular or substantially perpendicular to the upper surface 110s of the substrate 110) and may be on the green perovskite photodiode 250b. The third wavelength selective filter 80c may be overlapped with the red perovskite photodiode 250c in the red pixel 200c (e.g., overlapped in a vertical direction perpendicular or substantially perpendicular to the upper surface 110s of the substrate 110) and may be on the red perovskite photodiode 250c. The first wavelength selective filter 80a, the second wavelength selective filter 80b, and the third wavelength selective filter 80c may be different from each other and may be, for example, selected from a blue filter, a green filter, a red filter, a cyan filter, a yellow filter, and a magenta filter.

For example, the first wavelength selective filter 80a may be configured to selectively transmit light of a particular (or, alternatively, predetermined) wavelength spectrum including a blue wavelength spectrum among the visible wavelength spectrum, and may be, for example, a blue filter, a cyan filter, or a magenta filter.

For example, the second wavelength selective filter 80b may be configured to selectively transmit light of a particular (or, alternatively, predetermined) wavelength spectrum including a green wavelength spectrum among the visible wavelength spectrum, and may be, for example, a green filter, a cyan filter, or a yellow filter.

For example, the third wavelength selective filter 80c may be configured to selectively transmit light of a particular (or, alternatively, predetermined) wavelength spectrum including a red wavelength spectrum among the visible wavelength spectrum, and may be, for example, a red filter, a yellow filter, or a magenta filter.

For example, the first, second, and third wavelength selective filters 80a, 80b, and 80c may each be a blue filter, a green filter, and a red filter, respectively. For example, the first, second, and third wavelength selective filters 80a, 80b, and 80c may each be a cyan filter, a yellow filter, and a magenta filter, respectively.

In some example embodiments, the boundaries of the first, second, and third wavelength selective filters 80a, 80b, and 80c in the one or more horizontal directions and/or the horizontal plane (e.g., the xy direction and/or the xy plane) may define the boundaries of the respective blue, green, and red pixels 200a, 200b, and 200c in the one or more horizontal directions and/or the horizontal plane (e.g., the xy direction and/or the xy plane). In some example embodiments, the boundaries of the first electrodes 251a, 251b, and 251c in the one or more horizontal directions and/or the horizontal plane (e.g., the xy direction and/or the xy plane) may define the boundaries of the respective blue, green, and red pixels 200a, 200b, and 200c in the one or more horizontal directions and/or the horizontal plane (e.g., the xy direction and/or the xy plane).

The blue perovskite photodiode 250a, the green perovskite photodiode 250b, and the red perovskite photodiode 250c may include the first perovskite photoelectric conversion layer 253 in common. Restated, the blue perovskite photodiode 250a, the green perovskite photodiode 250b, and the red perovskite photodiode 250c may include separate portions of a single unitary piece of material defining the first perovskite photoelectric conversion layer 253. In addition, the first perovskite photoelectric conversion layer 253 may be configured to photoelectrically convert light passing through the first, second, and third wavelength selective filters 80a, 80b, and 80c according to regions. For example, the first perovskite photoelectric conversion layer 253 included in the blue perovskite photodiode 250a may be configured to photoelectrically convert light of a blue wavelength spectrum (or light including a blue wavelength spectrum) that has passed through the first wavelength selective filter 80a, such that the blue perovskite photodiode 250a may be configured to selectively sense light in the blue wavelength spectrum, the first perovskite photoelectric conversion layer 253 included in the green perovskite photodiode 250b may be configured to photoelectrically convert light of a green wavelength spectrum (or light including a green wavelength spectrum) that has passed through the second wavelength selective filter 80b, such that the green perovskite photodiode 250b may be configured to selectively sense light in the green wavelength spectrum, and the first perovskite photoelectric conversion layer 253 included in the red perovskite photodiode 250c may be configured to photoelectrically convert light of a red wavelength spectrum (or light including a red wavelength spectrum) that has passed through the third wavelength selective filter 80c, such that the red perovskite photodiode 250c may be configured to selectively sense light in the red wavelength spectrum.

Charges (holes or electrons) generated by photoelectric conversion in the first perovskite photoelectric conversion layer 253 in the blue perovskite photodiode 250a, the green perovskite photodiode 250b, and the red perovskite photodiode 250c may move to the first electrodes 251a, 251b, and 251c, respectively, and the second electrode 252, respectively, and the charges moved to the first electrodes 251a, 251b, and 251c may be collected in the charge storages 120a, 120b, and 120c, respectively.

The insulating layers 60 and 70 are between the first perovskite photodiode 250 and the substrate 110 and between the first perovskite photodiode 250 and the wavelength selective filter layer 80, respectively. The insulating layers 60 and 70 may each independently include an organic material, an inorganic material, an organic-inorganic material, or any combination thereof, and for example an inorganic insulating material such as a silicon oxide and/or a silicon nitride or a low dielectric constant (low K) material such as SiC, SiCOH, SiCO, and SiOF. At least one of the insulating layers 60 or 70 may be omitted.

The focusing lens 90 may be on the first perovskite photodiode 250 and wavelength selective filter layer 80 to control the direction of the incident light and collect the light to one point. The focusing lens 90 may have, for example, a cylindrical shape or a hemispherical shape, but is not limited thereto. A planarization layer 85 may be optionally between the focusing lens 90 and the wavelength selective filter layer 80. The planarization layer 85 may include an organic material, an inorganic material, an organic-inorganic material, or any combination thereof, and for example an inorganic insulating material such as a silicon oxide and/or a silicon nitride or a low dielectric constant (low K) material such as SiC, SiCOH, SiCO, and SiOF. The planarization layer 85 may be omitted.

As described above, perovskite may have about 10 times or more (e.g., about 10 times to 1000 times) higher absorbance than silicon, and thus higher light absorption characteristics than a conventional silicon photodiode. For example, a thickness 253t (e.g., a thickness in a vertical direction perpendicular to the upper surface 110s of the substrate 110) of the perovskite photoelectric conversion layer 253 absorbing the same amount of light may be reduced to about 1/10 or less than a thickness of a conventional silicon photodiode, and thus, a thickness (e.g., a thickness in a vertical direction perpendicular to the upper surface 110s of the substrate 110) of the image sensor 300 may also be greatly reduced and may be effectively applied as a thin-type image sensor. Accordingly, the image sensor 300, based on including the perovskite photodiodes 250, may have reduced size, and thus improved compactness and/or miniaturization, in comparison to an image sensor including a silicon-based photodiode, thereby enabling use as a thin-type image sensor, without compromising light absorbing and photoelectric conversion performance and/or light absorbing and photoelectric conversion efficiency of the image sensor 300.

The first perovskite photoelectric conversion layer 253 may have a relatively thin thickness 253t due to such high absorption characteristics, and may have a thickness 253t, for example, about 100 nm to about 800 nm, about 100 nm to about 700 nm, about 100 nm to about 500 nm, or about 200 nm to about 500 nm.

As described above, the perovskite may determine a cut-off wavelength of an absorption spectrum according to an energy bandgap and thus have wavelength selectivity. Accordingly, unlike silicon configured to uniformly absorb light of a broad wavelength spectrum from a short wavelength (near about 200 nm) to an infrared wavelength spectrum without the wavelength selectivity, the first perovskite photoelectric conversion layer 253 may exclude light of the infrared wavelength spectrum (e.g., may not absorb any or substantially any light of the infrared wavelength spectrum) but may absorb light of a visible wavelength spectrum, even without receiving light through a separate infrared blocking filter (e.g., even without the incident light on the perovskite photoelectric conversion layer 253 having already been at least partially filtered of infrared light). As a result, the image sensor 300 may have improved wavelength selectivity in comparison to image sensors including silicon-based photodiodes with regard to absorbing light excluding light of the infrared wavelength spectrum, including having such improved wavelength selectively without including a separate infrared filter to filter infrared light from the light that is incident on the perovskite photodiodes 250. As a result, the image sensor 300 may have improved photoelectric conversion performance and/or efficiency, improved wavelength selectively, and/or improved compactness and miniaturization (e.g., based on omitting a separate infrared filter) where the improved compactness and miniaturization is achieved without compromising photoelectric conversion performance, photoelectric conversion efficiency, and/or wavelength selectively.

In addition, the first perovskite photoelectric conversion layer 253 may have a refractive index of less than or equal to about 3.0 (e.g., about 0.0 to about 3.0, about 0.01 to about 3.0, about 0.1 to about 3.0, etc.), which may be lower than the refractive index of silicon (about 3.88 @630 nm). Accordingly, since an interfacial reflectance of the first perovskite photoelectric conversion layer 253 with the air is less than about 30%, less than or equal to about 28%, or less than or equal to about 25% (e.g., about 23%) based on an incident angle of 0°, while an interfacial reflectance of silicon with the air is about 35%, the first perovskite photoelectric conversion layer 253 instead of the silicon may be used to condense more light into the first perovskite photoelectric conversion layer 253 or not to form a separate anti-reflection coating.

In addition, the perovskite, compared with an organic photoelectric conversion material, has about 1000 times or more (e.g., about 1000 times to about 10⁶ times) higher charge mobility and thus higher photoelectric conversion efficiency and lower remaining charges characteristics in addition to higher light absorption characteristics. Accordingly, an image sensor 300 may have improved photoelectric conversion performance and/or efficiency based on including perovskite photodiodes 250 in relation to image sensors including organic photoelectric conversion devices. Accordingly, the perovskite may be effectively applied to high-performance image sensors such as high-speed driving sensors.

In addition, the perovskite may be applied to both solution processes such as spin coating, slit coating, and inkjet coating, and deposition processes such as vacuum deposition and thermal deposition, and thus it may have less process restrictions. As a result, manufacturing costs and/or complexity to manufacture an image sensor 300 may be reduced or minimized based on the image sensor 300 being manufactured to include perovskite photodiodes 250. Reduced manufacturing complexity may reduce a likelihood of process defects in the manufactured devices, thereby improving reliability of manufactured devices. Accordingly, manufacturing costs and/or complexity for processes to manufacture an image sensor 300 may be reduced, and/or the reliability of the image sensor 300 may be improved, based on the image sensor 300 including perovskite photodiodes 250.

Hereinafter, an example of an image sensor according to some example embodiments is described.

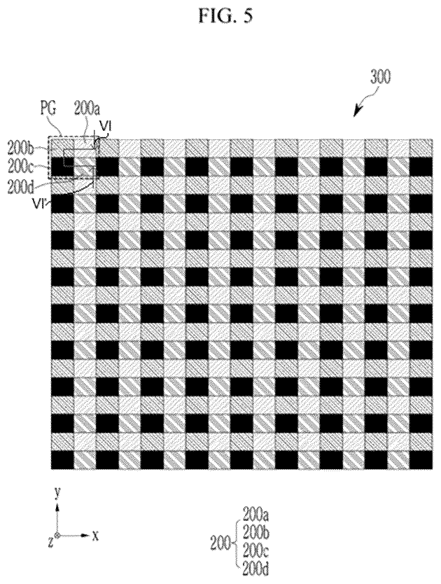

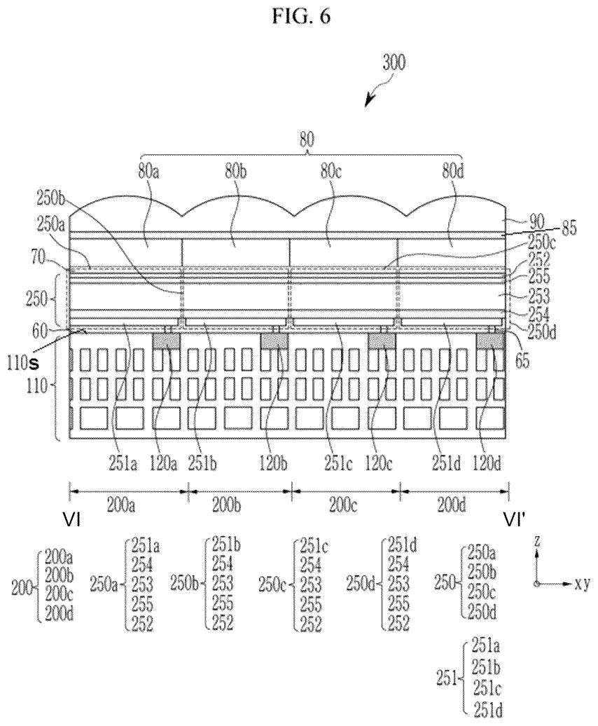

FIG. 5 is a plan view of an image sensor according to some example embodiments and FIG. 6 is a cross-sectional view of the image sensor of FIG. 5 according to some example embodiments. FIG. 6 may be a cross-sectional view along view line VI-VI′ in FIG. 5.

Referring to FIG. 5, an image sensor 300 according to some example embodiments, like the example embodiments shown in FIGS. 3-4, may include a plurality of pixels 200 respectively photoelectrically converting light of each first, second, and third wavelength spectrum belonging to a visible wavelength spectrum but differing one another, wherein each pixel 200 may be a blue pixel 200a configured to selectively sense light of a blue wavelength spectrum, a green pixel 200b configured to selectively sense light of a green wavelength spectrum, or a red pixel 200c configured to selectively sense light of a red wavelength spectrum.

In the image sensor 300 according to some example embodiments, including the example embodiments shown in FIGS. 5-6, unlike some example embodiments, including the example embodiments shown in FIGS. 3-4, the plurality of pixels 200 may further include an infrared pixel 200d. For example, one blue pixel 200a, one green pixel 200b, one red pixel 200c, and one infrared pixel 200d may form one pixel group PG and be repetitively arranged along rows and/or columns. The infrared pixel 200d may be configured to absorb and photoelectrically convert at least a portion of light of an infrared wavelength spectrum.

Referring to FIG. 6, an image sensor 300 according to some example embodiments includes a substrate 110, a first perovskite photodiode 250, a wavelength selective filter layer 80, insulating layers 60 and 70, and a focusing lens 90, like some example embodiments, including the example embodiments shown in FIGS. 3-4.

However, unlike some example embodiments, including the example embodiments shown in FIGS. 3-4, the first perovskite photodiode 250 further includes an infrared perovskite photodiode 250d included in the infrared pixel 200d in addition to the blue perovskite photodiode 250a included in blue pixel 200a, the green perovskite photodiode 250b included in in the green pixel 200b, and the red perovskite photodiode 250c included in the red pixel 200c. The blue perovskite photodiode 250a, the green perovskite photodiode 250b, the red perovskite photodiode 250c, and the infrared perovskite photodiode 250d are arranged along an in-plane direction (e.g., xy direction) of the substrate 110 to form a photodiode array.

The blue perovskite photodiode 250a, the green perovskite photodiode 250b, the red perovskite photodiode 250c, and the infrared perovskite photodiode 250d respectively include each first electrode 251a, 251b, 251c, and 251d, separate, respective portions of the second electrode 252, separate, respective portions of a first perovskite photoelectric conversion layer 253 between the first electrodes 251a, 251b, 251c, and 251d and the second electrode 252 (e.g., separate, respective portions of a single unitary piece of material defining the first perovskite photoelectric conversion layer 253), separate, respective portions of a lower auxiliary layer 254 between the first electrodes 251a, 251b, 251c, and 251d and the first perovskite photoelectric conversion layer 253, and separate, respective portions of an upper auxiliary layer 255 between the second electrode 252 and the first perovskite photoelectric conversion layer 253.

The first perovskite photoelectric conversion layer 253 may include the aforementioned perovskite, and may be commonly included in the blue perovskite photodiode 250a, the green perovskite photodiode 250b, the red perovskite photodiode 250c, and the infrared perovskite photodiode 250d. Restated, the blue perovskite photodiode 250a, the green perovskite photodiode 250b, the red perovskite photodiode 250c, and the infrared perovskite photodiode 250d may include separate, respective portions of a single, unitary piece of material that defines the first perovskite photoelectric conversion layer 253. In some example embodiments, the perovskite included in the first perovskite photoelectric conversion layer 253 may be configured to absorb light ranging from a visible wavelength spectrum to an infrared wavelength spectrum.

For example, the absorption spectrum of the perovskite may have a relatively high absorbance from a short wavelength (e.g., a wavelength belonging to an X-ray or UV-ray region) to an infrared wavelength spectrum. The perovskite may have an energy bandgap that matches (e.g., matches within 10% tolerance) the infrared wavelength spectrum.

For example, the cut-off wavelength of the absorption spectrum of the perovskite may be an endpoint of the infrared wavelength spectrum to be photoelectrically converted by the infrared perovskite photodiode 250d, and may belong to, for example, about 800 nm to about 3000 nm, within the above range, about 800 nm to about 2500 nm, about 800 nm to about 2200 nm, about 800 nm to about 2000 nm, about 800 nm to about 1800 nm, about 800 nm to about 1500 nm, about 800 nm to about 1300 nm, about 900 nm to about 2500 nm, about 900 nm to about 2200 nm, about 900 nm to about 2000 nm, about 900 nm to about 1800 nm, about 900 nm to about 1500 nm, about 900 nm to about 1300 nm, about 1000 nm to about 2500 nm, about 1000 nm to about 2200 nm, about 1000 nm to about 2000 nm, about 1000 nm to about 1800 nm, about 1000 nm to about 1500 nm, or about 1000 nm to about 1300 nm.

The wavelength selective filter layer 80 may include a first wavelength selective filter 80a included in the blue pixel 200a, a second wavelength selective filter 80b included in the green pixel 200b, and a third wavelength selective filter 80c included in the red pixel 200c and additionally, an infrared filter 80d included in an infrared pixel 200d.

In some example embodiments, the boundaries of the first, second, third wavelength selective filters 80a, 80b, and 80c and the infrared filter 80d in the one or more horizontal directions and/or the horizontal plane (e.g., the xy direction and/or the xy plane) may define the boundaries of the respective blue, green, red, and infrared pixels 200a, 200b, 200c, and 200d in the one or more horizontal directions and/or the horizontal plane (e.g., the xy direction and/or the xy plane). In some example embodiments, the boundaries of the first electrodes 251a, 251b, 251c, and 251d in the one or more horizontal directions and/or the horizontal plane (e.g., the xy direction and/or the xy plane) may define the boundaries of the respective blue, green, red, and infrared pixels 200a, 200b, 200c, and 200d in the one or more horizontal directions and/or the horizontal plane (e.g., the xy direction and/or the xy plane).

As described above, the first, second, and third wavelength selective filters 80a, 80b, and 80c may differ from one another, and the first wavelength selective filter 80a may be a blue filter, a cyan filter, or a magenta filter, the second wavelength selective filter 80b may be a green filter, a cyan filter, or a yellow filter, and the third wavelength selective filter 80c may be a red filter, a yellow filter, or a magenta filter. For example, the first, second, and third wavelength selective filters 80a, 80b, and 80c may be a blue filter, a green filter, and a red filter, respectively. For example, the first, second, and third wavelength selective filters 80a, 80b, and 80c may be a cyan filter, a yellow filter, and a magenta filter, respectively.

The infrared filter 80d may be overlapped with the infrared perovskite photodiode 250d in the vertical direction that is perpendicular or substantially perpendicular to the upper surface 110s. The infrared filter 80d may be configured to selectively transmit light of a predetermined infrared wavelength spectrum, and for example, may be configured to selectively transmit light of an infrared wavelength spectrum to be photoelectrically converted by the infrared perovskite photodiode 250d. The infrared filter 80d may be configured to selectively transmit light of a wavelength spectrum of, for example, greater than about 750 nm and less than or equal to about 3000 nm, within the above range, about 750 nm to about 3000 nm, about 750 nm to about 2500 nm, about 750 nm to about 2000 nm, about 750 nm to about 1800 nm, about 750 nm to about 1500 nm, about 800 nm to about 3000 nm, about 800 nm to about 2500 nm, about 800 nm to about 2000 nm, about 800 nm to about 1800 nm, or about 800 nm to about 1500 nm, but is not limited thereto.

The image sensor 300 according to some example embodiments additionally includes an infrared pixel 200d in addition to the image sensor 300 according to some example embodiments, including the example embodiments shown in FIGS. 3-4, and thereby thus sensitivity of the image sensor 300 in a low-light environment may be improved, and an ability to sense a three-dimensional image may be effectively improved by widening the dynamic range for detailed distinction between black and white contrast. In addition, the image sensor 300 may additionally include an infrared pixel and have a function of a security sensor, a vehicle sensor, or a biometric sensor.

Hereinafter, an example of an image sensor according to some example embodiments is described.

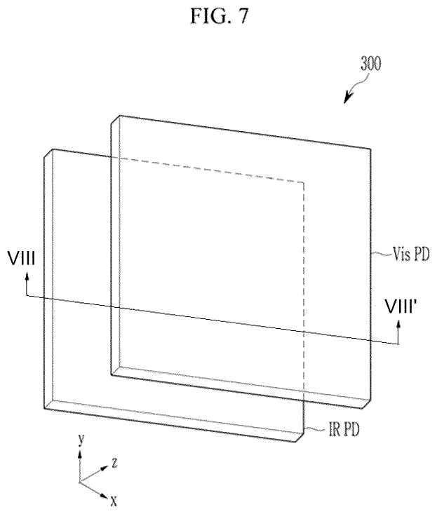

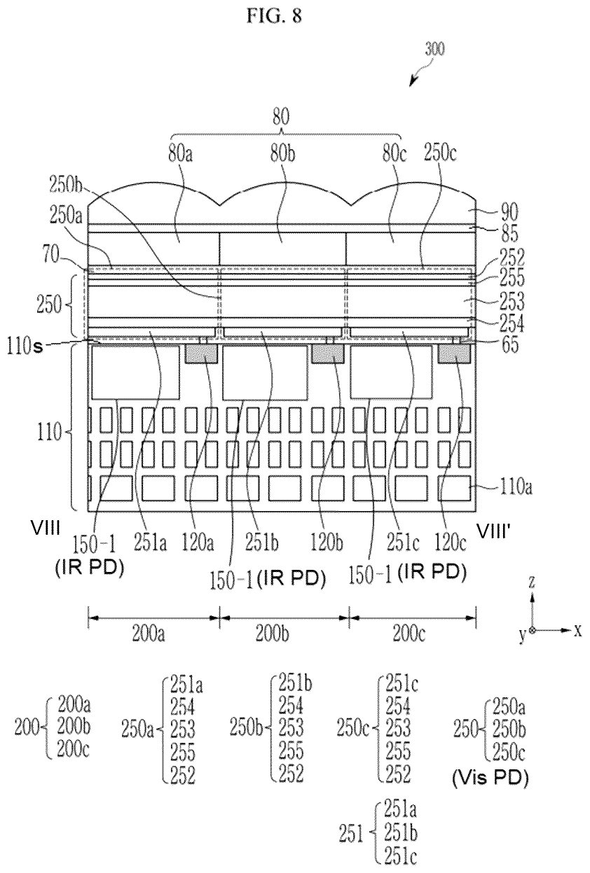

FIG. 7 is a perspective view of an image sensor according to some example embodiments and FIG. 8 is a cross-sectional view of the image sensor of FIG. 7 according to some example embodiments. FIG. 8 may be a cross-sectional view along view line VIII-VIII′ in FIG. 7.

Referring to FIG. 7, the image sensor 300 according to some example embodiments includes a visible photodiode (Vis PD) configured to absorb light of a visible wavelength spectrum and an infrared photodiode (IR PD) configured to sense light of an infrared wavelength spectrum. The visible photodiode (Vis PD) may be on the infrared photodiode (IR PD), and the visible photodiode (Vis PD) may be closer to the side where light is incident than the infrared photodiode (IR PD). Accordingly, incident light may pass through the visible photodiode (Vis PD) and be introduced into the infrared photodiode (IR PD). The visible photodiode (Vis PD) and the infrared photodiode (IR PD) are stacked along an incident direction of light. The visible photodiode (Vis PD) may include a first perovskite photodiode 250 configured to sense light in the visible wavelength spectrum.

Referring to FIG. 8, the image sensor 300 includes a substrate 110, a first perovskite photodiode 250, a wavelength selective filter layer 80, a silicon photodiode 150-1, insulating layers 60 and 70, and a focusing lens 90.

The substrate 110, the wavelength selective filter layer 80, the insulating layers 60 and 70, and the focusing lens 90 are the same as described above.

The first perovskite photodiode 250 may be the visible photodiode (Vis PD) of FIG. 7. The cut-off wavelength of the absorption spectrum of the perovskite included in the first perovskite photoelectric conversion layer 253 may be a boundary point between the visible wavelength spectrum and the infrared wavelength spectrum, and for example, may be greater than about 650 nm and less than about 750 nm, within the above range, about 670 nm to about 730 nm, about 680 nm to about 720 nm, or about 690 nm to about 710 nm. Accordingly, the first perovskite photoelectric conversion layer 253 may be configured to absorb light of a visible wavelength spectrum and transmit light of an infrared wavelength spectrum.

The silicon photodiode 150-1 may be an infrared photodiode (IR PD) of FIG. 7 and may be integrated into the substrate 110. The silicon photodiode 150-1 may be formed to a depth and thickness capable of absorbing infrared wavelength spectrum light within the substrate 110. For example, the thickness of the silicon photodiode 150-1 in a vertical direction z perpendicular or substantially perpendicular to the upper surface 110s of the substrate 110 may be about 1 μm to about 10 μm, and within the above range, about 2 μm to about 8 μm, or about 2 μm to about 6 μm.

Since the silicon photodiode 150-1 is under the aforementioned wavelength selective filter layer 80 and the first perovskite photodiode 250 to sense light passing through the wavelength selective filter layer 80 and the first perovskite photodiode 250, although the absorption spectrum of silicon widely spans from the short wavelength to the infrared wavelength spectrum, it may exclude the light of the short wavelength to the visible wavelength spectrum and selectively absorb the light of the infrared wavelength spectrum to photoelectrically convert it. For example, the transmittance of the infrared wavelength spectrum of the first perovskite photodiode 250 may be about 80% to about 100%, within the above range, about 85% to about 100%, about 90% to about 100%, and about 95% to about 100%, about 97% to about 100%, about 98% to about 100%, or about 99% to about 100%.

The image sensor 300 according to some example embodiments may be a stacked image sensor in which a first perovskite photodiode 250 and a silicon photodiode 150-1 which are configured to sense light of different wavelength spectrums are stacked. Accordingly, an in-pixel image sensor that realizes an image by simultaneously sensing light in the visible region and light in the infrared region within one pixel may be implemented. Therefore, unlike the structure in which the first perovskite photodiode 250 and the silicon photodiode 150-1 are manufactured on separate substrates, sensitivity of the image sensor 300 in a low-light environment may be improved without increasing the size of the image sensor 300, and by widening a dynamic range that separates black and white details, sensing ability of a three-dimensional image may be effectively increased, such that the photoelectric conversion performance and/or efficiency of the image sensor 300 may be improved, based on the image sensor 300 including a stacked image sensor in which a first perovskite photodiode 250 and a silicon photodiode 150-1 which are configured to sense light of different wavelength spectrums are stacked.

In addition, the silicon photodiode 150-1 may be used as a security sensor, a vehicle sensor, or a biometric sensor, and may be used as a composite sensor having composite functions of an image sensor, a security sensor, a vehicle sensor, or a biometric sensor due to the aforementioned stacked structure of the first perovskite photodiode 250 and silicon photodiode 150-1. Here, the biometric sensor may be, for example, an iris sensor, a distance sensor, a fingerprint sensor, or a blood vessel distribution sensor, but is not limited thereto.

Hereinafter, an example of an image sensor according to some example embodiments is described.

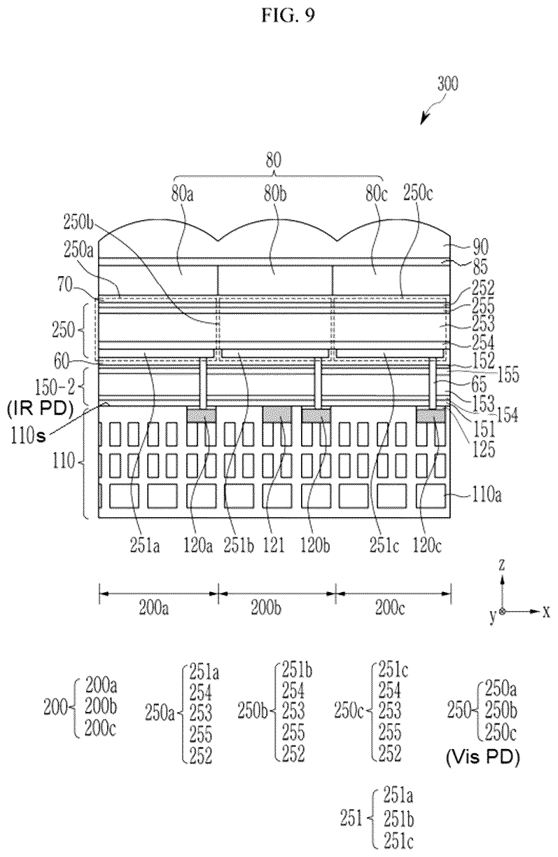

FIG. 9 is a cross-sectional view of the image sensor of FIG. 7 according to some example embodiments. FIG. 9 may be a cross-sectional view along view line VIII-VIII′ in FIG. 7.

Referring to FIG. 9, the image sensor 300 according to some example embodiments includes a substrate 110, a first perovskite photodiode 250, a wavelength selective filter layer 80, and a second perovskite photodiode 150-2, insulating layers 60 and 70, planarization layer 85, and a focusing lens 90.

The substrate 110, the first perovskite photodiode 250, the wavelength selective filter layer 80, the insulating layers 60 and 70, and the focusing lens 90 are the same as described above.

The second perovskite photodiode 150-2 may be an infrared photodiode (IR PD) of FIG. 7 and may be on the substrate 110. The second perovskite photodiode 150-2 may be on the entire upper surface 110s of the substrate 110 and may be stacked with the first perovskite photodiode 250 in the vertical direction (z direction) perpendicular or substantially perpendicular to the upper surface 110s in each pixel 200a, 200b, and 200c.

The second perovskite photodiode 150-2 may be configured to sense light of a longer wavelength spectrum than the first perovskite photodiode 250, that is, light of at least a portion of the infrared wavelength spectrum. The second perovskite photodiode 150-2 includes a third electrode 151, a fourth electrode 152, a second perovskite photoelectric conversion layer 153 between the third electrode 151 and the fourth electrode 152, a lower auxiliary layer 154 between the third electrode 151 and the second perovskite photoelectric conversion layer 153, and an upper auxiliary layer 155 between the fourth electrode 152 and the second perovskite photoelectric conversion layer 153.

One of the third electrode 151 or the fourth electrode 152 may be an anode and the other may be a cathode. For example, the third electrode 151 may be an anode and the fourth electrode 152 may be a cathode. For example, the third electrode 151 may be a cathode and the fourth electrode 152 may be an anode. The third electrode 151 may be, for example, a light transmitting electrode or a reflective electrode. The fourth electrode 152 may be, for example, a light transmitting electrode, and a description of the light transmitting electrode is as described above. The third electrode 151 may be electrically connected to the charge storage 121 integrated on the substrate 110, and the fourth electrode 152 may be an incident electrode in a direction in which light passing through the wavelength selective filter layer 80 and the first perovskite photoelectric conversion layer 253 is incident.

The second perovskite photoelectric conversion layer 153 may include a perovskite (hereinafter, referred to as ‘second perovskite’) that is different from the aforementioned perovskite included in the first perovskite photoelectric conversion layer 253, that is first perovskite. The second perovskite may be a Pb-free perovskite.

The second perovskite may be configured to absorb light of at least a portion of the infrared wavelength spectrum, and the infrared wavelength spectrum may include a portion or all of the near-infrared, short-wave infrared, mid-wave infrared, and far-infrared wavelength spectrum, for example greater than about 750 nm and less than or equal to about 3000 nm, within the above range, greater than about 750 nm and less than or equal to about 2500 nm, greater than about 750 nm and less than or equal to about 2000 nm, greater than about 750 nm and less than or equal to about 1800 nm, greater than about 750 nm and less than or equal to about 1500 nm, about 800 nm to about 3000 nm, about 800 nm to about 2500 nm, about 800 nm to about 2000 nm, about 800 nm to about 1800 nm, or about 800 nm to about 1500 nm, but is not limited thereto.

For example, the absorption spectrum of the second perovskite may have a relatively high absorbance from a short wavelength (e.g., a wavelength belonging to an X-ray or UV-ray region) to a wavelength included in an infrared wavelength spectrum. The second perovskite may have an energy bandgap that matches the infrared wavelength spectrum.

For example, the cut-off wavelength of the absorption spectrum of the second perovskite may be the end-point of the infrared wavelength spectrum to be photoelectrically converted and may be a longer wavelength than the cut-off wavelength of the absorption spectrum of the aforementioned first perovskite. For example, the cut-off wavelength of the absorption spectrum of the second perovskite may belong to, for example, about 800 nm to about 3000 nm, and within the above range, about 800 nm to about 2500 nm, about 800 nm to about 2200 nm, about 800 nm to about 2000 nm, about 800 nm to about 1800 nm, about 800 nm to about 1500 nm, about 800 nm to about 1300 nm, about 900 nm to about 2500 nm, about 900 nm to about 2200 nm, about 900 nm to about 2000 nm, about 900 nm to about 1800 nm, about 900 nm to about 1500 nm, about 900 nm to about 1300 nm, about 1000 nm to about 2500 nm, about 1000 nm to about 2200 nm, about 1000 nm to about 2000 nm, about 1000 nm to about 1800 nm, about 1000 nm to about 1500 nm, or about 1000 nm to about 1300 nm.

Charges (holes or electrons) generated by photoelectric conversion in the second perovskite photoelectric conversion layer 153 may move to the third electrode 151 and the fourth electrode 152, respectively, and the charges moved to the third electrode 151 may be collected in the charge storage 121.

The lower auxiliary layer 154 may be the same as the aforementioned lower auxiliary layer 254, and the upper auxiliary layer 155 may be the same as the aforementioned upper auxiliary layer 255.

Since the second perovskite photodiode 150-2 is under the aforementioned wavelength selective filter layer 80 and the first perovskite photodiode 250 to sense light passing through the wavelength selective filter layer 80 and the first perovskite photodiode 250, although the absorption spectrum of the second perovskite widely spans from the short wavelength (e.g., X-rays, UV light, etc.) to the infrared wavelength spectrum, the second perovskite photodiode 150-2 may exclude the light of the short wavelength to the visible wavelength spectrum (e.g., may not any or substantially any light of the short wavelength to the visible wavelength spectrum) and selectively absorb the light of the infrared wavelength spectrum to photoelectrically convert it. For example, the transmittance of the infrared wavelength spectrum of the first perovskite photodiode 250 may be about 80% to about 100%, within the above range, about 85% to about 100%, about 90% to about 100%, and about 95% to about 100%, about 97% to about 100%, about 98% to about 100%, or about 99% to about 100%. Due to the second perovskite photodiode 150-2, the substrate 110 may not include a separate silicon photodiode (e.g., may not include any separate silicon photodiodes).

The aforementioned image sensors may be included in an imaging device such as a camera, and such an image sensor and/or camera may be for example applied to various electronic devices such as a smartphone, a mobile phone, a tablet PC, a laptop PC, a desktop PC, an e-book, a navigation device, TV, PDA (personal digital assistant), PMP (portable multimedia player), EDA (enterprise digital assistant), a wearable computers, Internet of Things devices (IoT), Internet of Things (IoE), a drone, a digital camera, a door lock, a safe, automated teller machines (ATMs), a security device, a medical device, or automotive electronic components.

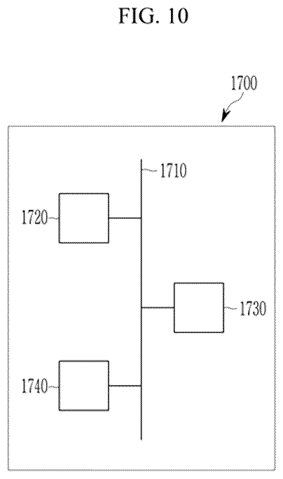

FIG. 10 is a schematic view of an electronic device according to some example embodiments.

Referring to FIG. 10, an electronic device 1700 may include a processor 1720 (e.g., a central processing unit or CPU), a memory 1730 (e.g., a solid state drive (SSD) storage device), and an image sensor 1740 electrically connected to each other through a bus 1710. The image sensor 1740 may be the same as described above (e.g., image sensor 300 according to any of the example embodiments). The memory 1730, which may be a non-transitory computer readable medium (e.g., a SSD storage device), may store a program of instructions. The processor 1720 (e.g., a CPU) may execute the stored program of instructions to perform one or more functions. For example, the processor 1720 may be configured to process electrical signals generated by the image sensor 1740. The processor 1720 may be configured to generate an output (e.g., an image to be displayed on a display interface) based on such as processing.

The electronic device 1700 and/or any portion thereof (e.g., processor 1720, memory 1730, etc.) may include processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), or the like. As an example, the processing circuitry may include a non-transitory computer readable storage device. The processor 1720 (e.g., a central processing unit or CPU) may, for example, control an operation of the image sensor 1740, for example based on executing an instruction program stored at the memory 1730 (e.g., a solid-state drive (SSD) storage device).

Hereinafter, some example embodiments are illustrated in more detail with reference to examples. However, the present scope of the inventive concepts is not limited to these examples.

### PREPARATION EXAMPLES: PREPARATION OF PEROVSKITE PRECURSOR

### Preparation Example 1

0.756 mmol of formamidinium iodide (FAI), 0.135 mmol of methylammonium chloride (MACI), ethylenediammonium diiodide (EDAl₂), 0.009 mmol of ethylenediammonium diiodide (EDAl₂), and 0.9 mmol of tin(II) iodide (SnI₂) are added to 1 ml of a mixed solvent of dimethyl formamide (DMF) and dimethylsulfoxide (DMSO) (DMF:DMSO=4:1 (a volume ratio)) and then, stirred under a nitrogen atmosphere at room temperature for 2 hours to prepare a FA_{0.84}MA_{0.15}EDA_{0.01}SnI_{2.85}Cl_{0.15} Pb-free perovskite precursor solution.

### Preparation Example 2

0.801 mmol of formamidinium iodide (FAI), 0.09 mmol of p-fluoro-phenethylammonium bromide (p-F-PEABr), 0.009 mmol of ethylenediammonium diiodide (EDAl₂), and 0.9 mmol of tin(II) iodide (SnI₂) are added to 1 ml of a mixed solvent of dimethyl formamide (DMF) and dimethylsulfoxide (DMSO) (DMF:DMSO=4:1 (a volume ratio)) and then, stirred under a nitrogen atmosphere at room temperature for 2 hours to prepare a FA_{0.89}(F-PEA)_{0.10}EDA_{0.01}SnI_{2.90}Br_{0.10} Pb-free perovskite precursor solution.

### Comparative Preparation Example 1

0.89 mmol of formamidinium iodide (FAI), 0.01 mmol of ethylenediammonium diiodide (EDAl₂), and 0.9 mmol of tin(II) iodide (SnI₂) are added to 1 ml of a mixed solvent of dimethyl formamide (DMF) and dimethylsulfoxide (DMSO) (DMF:DMSO=4:1 (a volume ratio)) and then, stirred under a nitrogen atmosphere at room temperature for 2 hours to prepare a FA_{0.99}EDA_{0.01}SnI₃ Pb-free perovskite precursor solution.

### Synthesis Example: Synthesis of Compound for Auxiliary Layer

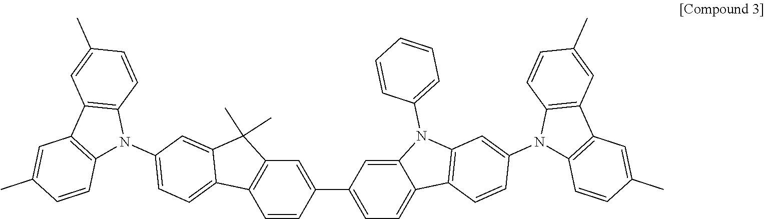

### (1) Synthesis of Compound 1

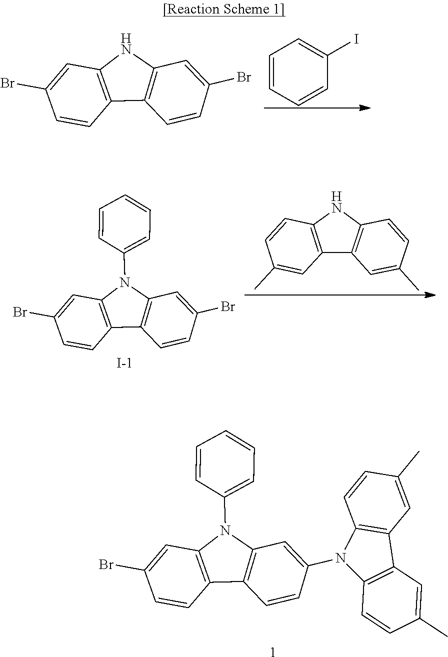

### i) Synthesis of Intermediate 1 (I-1)

3.08 g (9.47 mmol) of 2,7-dibromo-9H-carbazole and 2.32 g (11.37 mmol) of iodobenzene are dissolved in 50 ml of anhydrous toluene and then, heated under reflux under the presence of 10 mol % of Pd(dba)₂, 20 mol % of P(t-Bu)₃, and 2.73 g (28.42 mmol) of sodium t-butoxide (NaOtBu) for 8 hours. After removing organic solvents, the obtained product is separated and purified through silica gel column chromatography to obtain 3.27 g of 2,7-dibromo-9-phenyl-9H-carbazole (Intermediate 1, I-1).

### ii) Synthesis of Compound 1

3.27 g (8.15 mmol) of Intermediate 1 (I-1) and 1.91 g (9.78 mmol) of 3,6-dimethyl-9H-carbazole are dissolved in 50 ml of anhydrous toluene and then, heated under reflux under the presence of 10 mol % of Pd(dba)₂, 20 mol % of P(t-Bu)₃, and 2.35 g (24.44 mmol) of sodium t-butoxide (NaOtBu) for 8 hours. After removing organic solvents, the obtained product is separated and purified through silica gel column chromatography to obtain 3.53 g of 7-bromo-3′,6′-dimethyl-9-phenyl-9H-2,9′-bicarbazole (Compound 1). A yield is 84%.

### (2) Synthesis of Compound 2

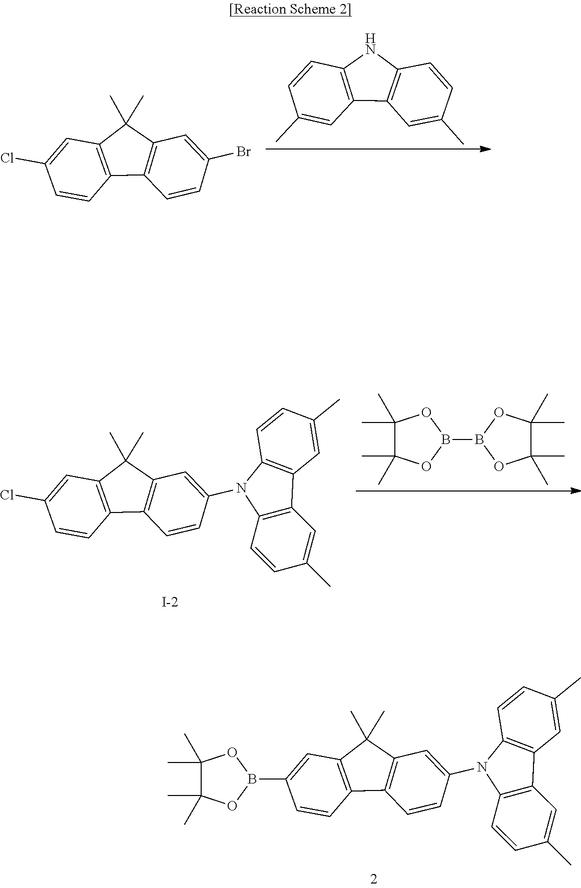

### i) Synthesis of Intermediate 2 (I-2)

3.28 g (10.66 mmol) of 2-bromo-7-chloro-9,9-dimethyl-9H-fluorene and 2.50 g (12.80 mmol) of 3,6-dimethyl-9H-carbazole are dissolved in 50 ml of anhydrous toluene and then, heated under reflux under the presence of 10 mol % of Pd(dba)₂, 20 mol % of P(t-Bu)₃, and 3.08 g (31.99 mmol) of sodium t-butoxide (NaOtBu) for 8 hours. After removing organic solvents, the obtained product is separated and purified through silica gel column chromatography to obtain 3.98 g of 9-(7-chloro-9,9-dimethyl-9H-fluoren-2-yl)-3,6-dimethyl-9H-carbazole (Intermediate 2, I-2). A yield is 88%.

### ii) Synthesis of Compound 2

3.12 g (7.40 mmol) of Intermediate 2 (I-2) and 2.01 g (8.14 mmol) of 4,4,4′,4′,5,5,5′,5′-octamethyl-2,2′-bi(1,3,2-dioxaborolane) are dissolved in 30 ml of dioxane, and 2.18 g (22.20 mmol) of potassium acetate is added thereto and then, heated under reflux for 12 hours. When a reaction is completed, after extraction with methylenechloride (MC) and H₂O, an extract therefrom is separated and purified through silica gel column chromatography to obtain 3.10 g of 9-(9,9-dimethyl-7-(4,4,5,5-tetramethyl-1,3,2-dioxaborolan-2-yl)-9H-fluoren-2-yl)-3,6-dimethyl-9H-carbazole (Compound 2). A yield is 82%.

### (3) Synthesis of Compound 3

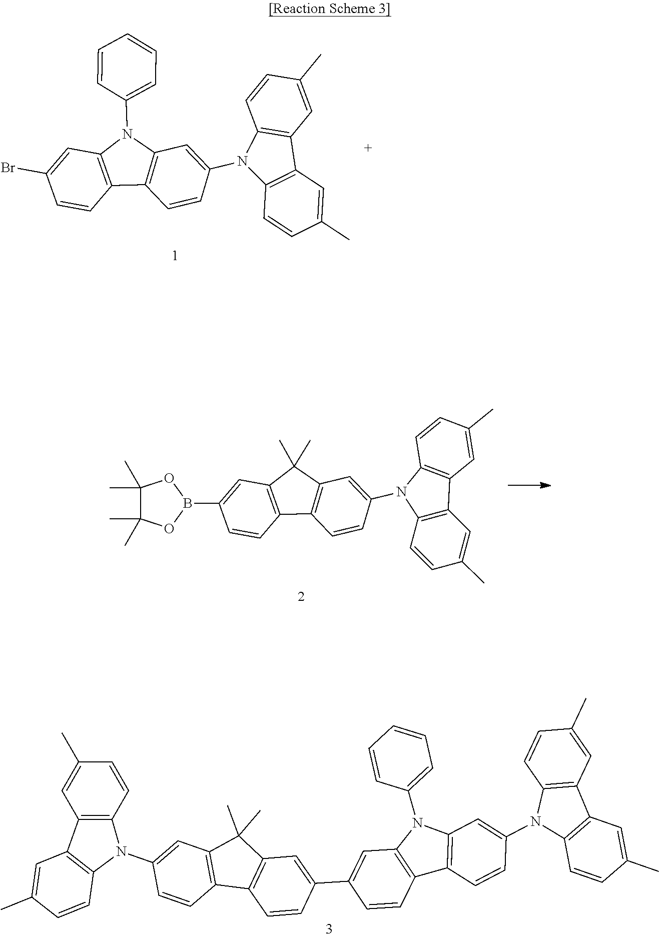

2.51 g (4.87 mmol) of Compound 1, 2.50 g (4.87 mmol) of Compound 2, 0.281 g (0.24 mmol) of Pd(PPh₃)₄, and 2.02 g (14.6 mmol) of K₂CO₃ are dissolved in 50 ml of THF/H₂O (a volume ratio of 2:1) and then, heated under reflux at 80° C. for 12 hours. Subsequently, after extraction with water and ethylether, the obtained product is separated and purified through silica gel column chromatography to obtain 3.23 g of 7-(7-(3,6-dimethyl-9H-carbazol-9-yl)-9,9-dimethyl-9H-fluoren-2-yl)-3′,6′-dimethyl-9-phenyl-9H-2,9′-bicarbazole (Compound 3). A yield is 81%.

1H NMR (500 MHz, CDCl3): δ 8.35 (d, 1H), 8.30 (d, 1H), 7.95-7.91 (m, 4H), 7.85 (d, 1H), 7.76 (s, 1H), 7.71-7.69 (m, 3H), 7.67-7.59 (m, 6H), 7.56-7.53 (m, 2H), 7.50-7.45 (m, 2H), 7.38 (d, 2H), 7.34 (d, 2H), 7.26-7.20 (m, 4H), 2.57 (s, 6H), 2.55 (s, 6H), 1.61 (s, 6H)

### Evaluation I

Energy levels of the Compound 3 obtained in Synthesis Example is evaluated.

A HOMO energy level is evaluated by using AC-3 (Riken Keiki Co., LTD.) to irradiate a thin film with UV light and then, measure an amount of photoelectrons emitted according to energy, and a LUMO energy level is evaluated by obtaining an energy bandgap by a UV-Vis spectrometer (Shimadzu Corporation) and using this energy bandgap and the HOMO energy level.

The results are shown in Table 1.

TABLE 1

| | HOMO (eV) | LUMO (eV) | Eg (eV) |
|---|---|---|---|
| Compound 3 | 5.62 | 2.61 | 3.01 |

* HOMO, LUMO: absolute value
* Eg: energy bandgap

### Evaluation II

Heat resistance properties of the Compound 3 according to Synthesis Examples are evaluated.

The heat resistance properties are evaluated from a weight loss according to a temperature increase under high vacuum of less than or equal to 10 Pa, and each temperature where 10 wt % and 50 wt % of a weight relative to an initial weight are respectively lost is described as Ts₁₀ and Ts₅₀.

A glass transition temperature (Tg) and a crystallization temperature (Tc) are measured by using a differential scanning calorimeter (DSC) (Model name: Discovery DSC, Manufacturer: TA Instruments).

A melting point (Tm) is measured through differential thermal analysis (DTA) (Model name: TG-DTA2000SE, Manufacturer: NETZSCH) under a normal pressure.

Single-film heat resistance is evaluated by depositing a compound into a 30 nm-thick single film on an Si wafer and examining the film with an optical electron microscope (OEM) to obtain a highest temperature where single-film crystallization does not proceed.

The results are shown in Table 2.

TABLE 2

| | Compound 3 |
|---|---|
| Glass transition temperature (Tg)(° C.) | 200.1 |
| Crystallization temperature (Tc) (° C.) | 281.4 |
| Melting temperature (Tm) (° C.) | 298 |
| Tₛ₁₀ (° C.) | 342 |
| Tₛ₅₀ (° C.) | 372 |
| Single-film heat resistance (° C.) | 200 |

* Tₛ₁₀: a temperature where a weight loss by 10 wt % of the initial weight
* Tₛ₅₀: a temperature where a weight loss by 50 wt % of the initial weight

### Manufacture of Photodiodes

### Example 1

ITO is deposited on a glass substrate to form a 100 nm-thick lower electrode (work function: 4.6 to 4.7 eV). Subsequently, Compound 3 according to Synthesis Example is deposited on the lower electrode to form a 5 nm-thick lower auxiliary layer (HOMO: 5.62 eV, LUMO: 2.61 eV). Subsequently, the perovskite precursor solution according to Preparation Example 1 is spin-coated on the lower auxiliary layer at 8000 rpm for 60 seconds and annealed at 80° C. for 15 minutes, to form a perovskite photoelectric conversion layer including Pb-free perovskite represented by FA_{0.84}MA_{0.15}EDA_{0.01}SnI_{2.85}Cl_{0.15}. Then, fullerene C60 of 20 nm, BCP of 4 nm, and Ag of 100 nm are sequentially thermally deposited on the perovskite photoelectric conversion layer, at about 0.1 to 0.3 Å/s under high vacuum (<3.0×10⁻⁶ Torr) to form an upper auxiliary layer and an upper electrode, manufacturing a photodiode.

### Example 2

A photodiode is manufactured in the same manner as Example 1, except that a perovskite photoelectric conversion layer including Pb-free perovskite represented by FA_{0.89}(F-PEA)_{0.10}EDA_{0.01}SnI_{2.90}Br_{0.10} is formed using the Pb-free perovskite precursor solution obtained in Preparation Example 2 instead of the Pb-free perovskite precursor solution obtained in Preparation Example 1.

### Comparative Example 1

A photodiode is manufactured in the same manner as Example 1, except that a perovskite photoelectric conversion layer including Pb-free perovskite represented by FA_{0.99}EDA_{0.01}SnI₃ is formed using the Pb-free perovskite precursor solution obtained in Comparative Preparation Example 1 instead of the Pb-free perovskite precursor solution obtained in Preparation Example 1.

### Evaluation III

Photoelectric conversion efficiency of the photodiodes according to Examples and Comparative Example are evaluated.

The photoelectric conversion efficiency is evaluated from external quantum efficiency (EQE), and the external quantum efficiency (EQE) is measured by applying a reverse bias voltage of 0 V to −3 V to the photodiodes for an absorption wavelength (A) 320 nm to 1000 nm in an Incident Photon to Current Efficiency (IPCE) method.

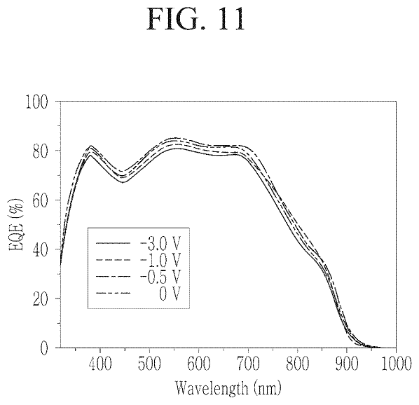

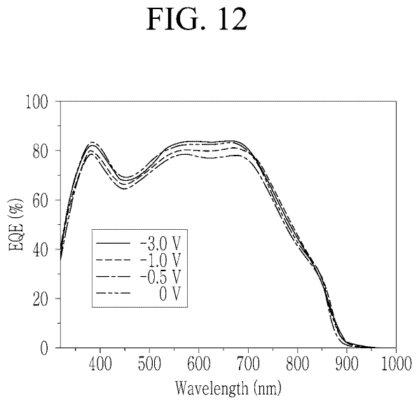

The results are shown in FIGS. 11 and 12.

FIG. 11 is a graph showing the external quantum efficiency (EQE) according to the wavelength of the photodiode according to Example 1, and FIG. 12 is a graph showing the external quantum efficiency (EQE) according to the wavelength of the photodiode according to Example 2.

Referring to FIGS. 11 and 12, the photodiodes according to Examples exhibits high external quantum efficiency (EQE) in the wavelength range of about 400 nm to 700 nm.

### Evaluation IV

The dark current density of the photodiodes according to Examples 1 and 2 and a Comparative Example 1 is evaluated.

A dark current is evaluated by using a current-voltage evaluation equipment (Keithley K4200 Parameter Analyzer) and divided by a unit pixel area (0.04 cm²) to obtain dark current density, and the dark current density is evaluated from a current flowing when a reverse bias of −1 V is applied.

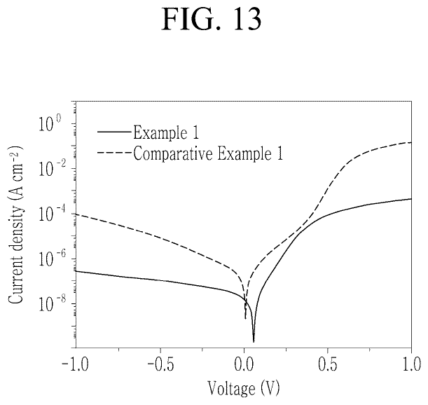

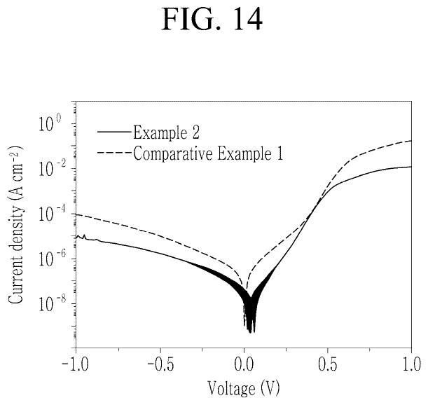

The results are shown in FIGS. 13 and 14.

FIG. 13 is a graph showing the dark currents of the photodiodes according to Example 1 and Comparative Example 1 and FIG. 14 is a graph showing the dark currents of the photodiodes according to Example 2 and Comparative Example 1.

Referring to FIGS. 13 and 14, the dark current characteristics of the photodiodes according to Examples 1 and 2 are improved compared to the photodiode according to Comparative Example 1.

### Evaluation V

The detectivity (D) of the photodiodes according to Examples and Comparative Example is evaluated.

The detectivity may be calculated by Equations 1 and 2.

$$R ( A / W ) = EQE / hv \qquad [ Equation 1 ]$$

In Equation 1, R is a ratio of photocurrent to incident light power, EQE is the external quantum efficiency, and hv is the incident light energy (eV), and

$$D = R / {( 2 {qJ}_{d} )}^{0.5} \qquad [ Equation 2 ]$$

in Equation 2, D is detectivity, R is as defined in Equation 1, q is electric charge, and J_{d} is dark current density.

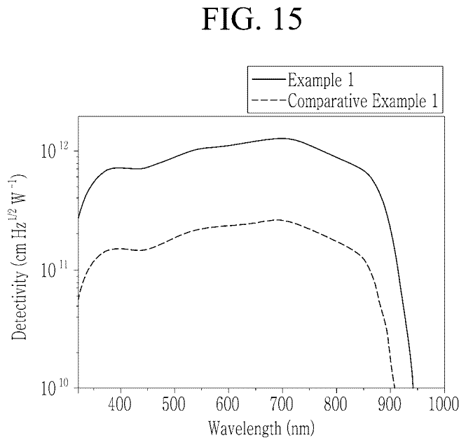

The results are shown in FIGS. 15 to 18.

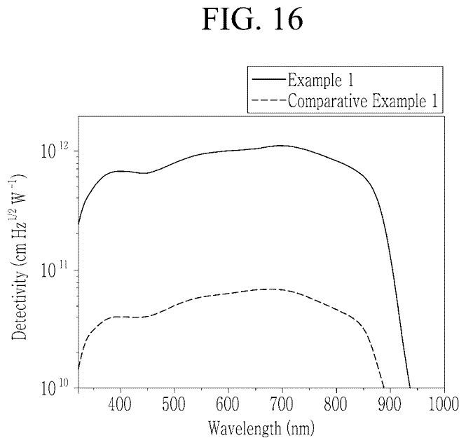

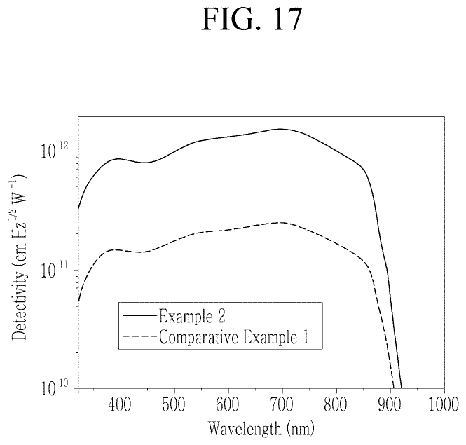

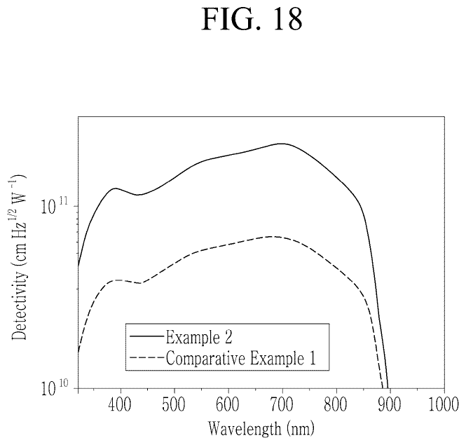

FIG. 15 is a graph showing detectivity according to wavelength when a voltage of −0.5 V is applied to the photodiodes according to Example 1 and Comparative Example 1, FIG. 16 is a graph showing detectivity according to wavelength when a voltage of −1.0 V is applied to the photodiodes according to Example 1 and Comparative Example 1, FIG. 17 is a graph showing detectivity according to wavelength when a voltage of −0.5 V is applied to the photodiodes according to Example 2 and Comparative Example 1, and FIG. 18 is a graph showing detectivity according to wavelength when a voltage of −1.0 V is applied to the photodiodes according to Example 2 and Comparative Example 1.

Referring to FIGS. 15 to 18, the photodiodes according to Examples 1 and 2 have improved detectivity compared to the photodiode according to Comparative Example 1.

While the inventive concepts have been described in connection with what is presently considered to be practical example embodiments, it is to be understood that the inventive concepts are not limited to such example embodiments. On the contrary, the inventive concepts are intended to cover various modifications and equivalent arrangements included within the spirit and scope of the appended claims.

What is claimed is:

1. A perovskite photodiode, comprising:
a first electrode;
a second electrode;
a perovskite photoelectric conversion layer between the first electrode and the second electrode, the perovskite photoelectric conversion layer including a Pb-free perovskite represented by Chemical Formula 1; and
an auxiliary layer between the first electrode and the perovskite photoelectric conversion layer, the auxiliary layer including an organic compound represented by Chemical Formula 2: 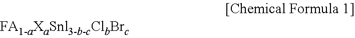
wherein, in Chemical Formula 1,
FA is formamidinium,
X is a substituted or unsubstituted methyl ammonium, a substituted or unsubstituted ethylene diammonium, a substituted or unsubstituted C6 to C12 aromatic alkylammonium, a substituted or unsubstituted C1 to C10 aliphatic ammonium, Cs⁺, Rb⁺, K⁺, Na⁺, or any combination thereof,
$$0 \leq a \leq 1 , 0 \leq b \leq 1 , and 0 \leq c \leq 1 ,$$
at least one of b or c is not 0, 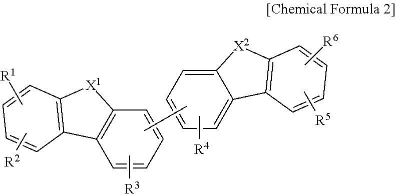
wherein, in Chemical Formula 2,
X¹ and X² are different from each other, and X¹ and X² are each independently one of CR^{a}R^{b}, SiR^{c}R^{d}, or NR^{e},
R¹ to R⁶ are each independently hydrogen, a substituted or unsubstituted C1 to C30 alkyl group, a substituted or unsubstituted C1 to C30 alkoxy group, a substituted or unsubstituted C6 to C20 aryl group, a substituted or unsubstituted C3 to C20 heterocyclic group, a halogen, a cyano group, —NR^{f}R^{g}, or any combination thereof,
at least one of R¹ or R⁶ is a substituted or unsubstituted C6 to C20 aryl group, a substituted or unsubstituted C3 to C20 heterocyclic group, —NR^{f}R^{g}, or any combination thereof,
R^{a} to R^{g} are each independently hydrogen, a substituted or unsubstituted C1 to C30 alkyl group, a substituted or unsubstituted C6 to C20 aryl group, a substituted or unsubstituted C3 to C20 heterocyclic group, a halogen, a cyano group, or any combination thereof,
R^{a} and R^{b} are each independently present or are combined with each other to form a first ring,
R^{c} and R^{d} are each independently present or are combined with each other to form a second ring, and
R^{f} and R^{g} are each independently present or are combined with each other to form a third ring.

2. The perovskite photodiode of claim 1, wherein in Chemical Formula 1, a, b, and c satisfy 0<a≤0.5 and 0<(b+c)≤0.5.

3. The perovskite photodiode of claim 1, wherein
the Pb-free perovskite includes FA₁₋ₐMAₐSnI_{3-b-c}Cl_{b}Br_{c}, FA₁₋ₐEDAₐSnI_{3-b-c}Cl_{b}Br_{c}, FA₁₋ₐ(F-PEA)ₐSnI_{3-b-c}Cl_{b}Br_{c}, FA₁₋ₐ₁₋ₐ₂(MA)ₐ₁(EDA)ₐ₂SnI_{3-b-c}Cl_{b}Br_{c}, FA₁₋ₐ₁₋ₐ₂(MA)ₐ₁(Cs)ₐ₂SnI_{3-b-c}Cl_{b}Br_{c}, FA₁₋ₐ₁₋ₐ₂(EDA)ₐ₁(Cs)ₐ₂SnI_{3-b-c}Cl_{b}Br_{c}, FA₁₋ₐ₁₋ₐ₂(F-PEA)ₐ₁(Cs)ₐ₂SnI_{3-b-c}Cl_{b}Br_{c}, FA₁₋ₐ₁₋ₐ₂(MA)ₐ₁(EDA)ₐ₂SnI_{3-b-c}Cl_{b}Br_{c}, FA₁₋ₐ₁₋ₐ₂(F-PEA)ₐ₁(EDA)ₐ₂SnI_{3-b-c}Cl_{b}Br_{c}, FA₁₋ₐ₁₋ₐ₂(F-PEA)ₐ₁(MA)ₐ₂SnI_{3-b-c}Cl_{b}Br_{c}, or any combination thereof,
FA is formamidinium, MA is methyl ammonium, EDA is ethylene diammonium, F-PEA is fluorine-substituted phenethylammonium, and
$$0 < a \leq 0.5 , 0 < ( a 1 + a 2 ) \leq 0.5 , 0 \leq a 1 \leq 0.5 , \\ 0 \leq a 2 \leq 0.5 , 0 \leq b \leq 0.5 , 0 \leq c \leq 0.5 , and 0 < ( b + c ) \leq 0.5 .$$

4. The perovskite photodiode of claim 1, wherein
in Chemical Formula 2, X¹ is CR^{a}R^{b} or SiR^{c}R^{d}, wherein R^{a} to R^{d} are each independently hydrogen, a substituted or unsubstituted C1 to C30 alkyl group or a substituted or unsubstituted C6 to C20 aryl group, and
in Chemical Formula 2, X² is NR^{e}, wherein R^{e} is a substituted or unsubstituted C6 to C20 aryl group.

5. The perovskite photodiode of claim 1, wherein in Chemical Formula 2,
R¹ and R⁶ are each —NR^{f}R^{g}, wherein R^{f} and R^{g} are each a substituted or unsubstituted C6 to C20 aryl group,
R^{f} and R^{g} are bonded to form a ring through a single bond, a substituted or unsubstituted C1 to C5 alkylrene group, a substituted or unsubstituted C2 to C5 alkenylene group, a substituted or unsubstituted C6 to C20 arylene group, O, S, Se, Te, CR^{h}Rⁱ, SiR^{j}R^{k}, or GeR^{l}R^{m}, and
R^{h} to R^{m} are each independently hydrogen, a substituted or unsubstituted C1 to C30 alkyl group, a substituted or unsubstituted C6 to C20 aryl group, a substituted or unsubstituted C3 to C20 heterocyclic group, a halogen, a cyano group, or any combination thereof.

6. The perovskite photodiode of claim 1, wherein the organic compound is represented by Chemical Formula 2A: 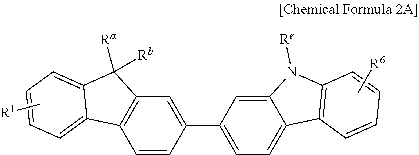
wherein, in Chemical Formula 2A,
R^{a} and R^{b} are each independently hydrogen, a substituted or unsubstituted C1 to C30 alkyl group or a substituted or unsubstituted C6 to C20 aryl group,
R^{e} is a substituted or unsubstituted C6 to C20 aryl group, and
R¹ and R⁶ are each one group of a plurality of groups listed in Group 1, 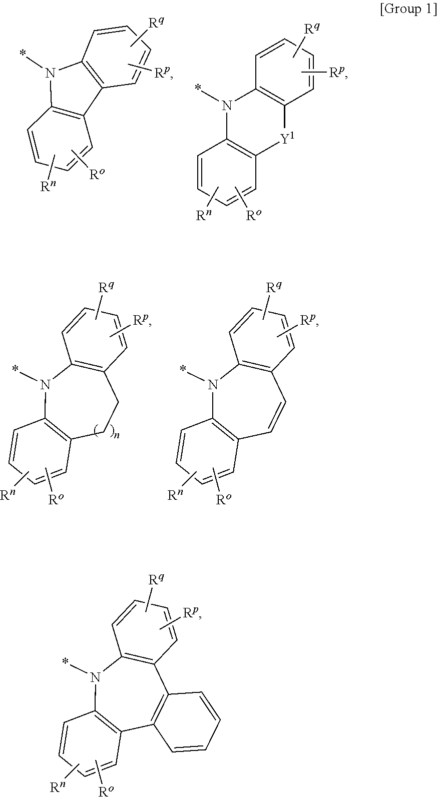
wherein, in Group 1,
Y¹ is O, S, Se, Te, CR^{h}Rⁱ, SiR^{j}R^{k}, or GeR^{l}R^{m},
R^{h} to R^{q} are each independently hydrogen, a substituted or unsubstituted C1 to C30 alkyl group, a substituted or unsubstituted C6 to C20 aryl group, a substituted or unsubstituted C3 to C20 heterocyclic group, a halogen, a cyano group, or any combination thereof,
n is an integer from 0 to 2, and
* is a linking point with Chemical Formula 2A.

7. An image sensor comprising the perovskite photodiode of claim 1.

8. An image sensor, comprising:
a substrate;
a first perovskite photodiode on the substrate; and
a wavelength selective filter layer overlapped with the first perovskite photodiode, the wavelength selective filter layer including a plurality of wavelength selective filters,
wherein the first perovskite photodiode includes
a first electrode,
a second electrode,
a first perovskite photoelectric conversion layer between the first electrode and the second electrode, the first perovskite photoelectric conversion layer including a first Pb-free perovskite represented by Chemical Formula 1, and
a first auxiliary layer between the first electrode and the first perovskite photoelectric conversion layer, the first auxiliary layer including an organic compound represented by Chemical Formula 2: 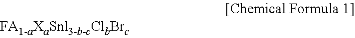
wherein, in Chemical Formula 1,
FA is formamidinium,
X is a substituted or unsubstituted methyl ammonium, a substituted or unsubstituted ethylene diammonium, a substituted or unsubstituted C6 to C12 aromatic alkylammonium, a substituted or unsubstituted C1 to C10 aliphatic ammonium, Cs⁺, Rb⁺, K⁺, Na⁺, or any combination thereof, and
$$0 \leq a \leq 1 , 0 \leq b \leq 1 , and 0 \leq c \leq 1 ,$$
at least one of b or c is not 0, 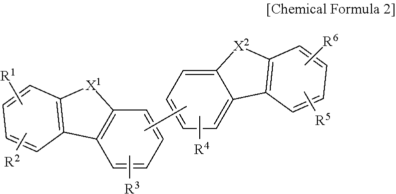
wherein, in Chemical Formula 2,
X¹ and X² are different, and X¹ and X² are each independently one of CR^{a}R^{b}, SiR^{c}R^{d}, or NR^{e},
R¹ to R⁶ are each independently hydrogen, a substituted or unsubstituted C1 to C30 alkyl group, a substituted or unsubstituted C1 to C30 alkoxy group, a substituted or unsubstituted C6 to C20 aryl group, a substituted or unsubstituted C3 to C20 heterocyclic group, a halogen, a cyano group, —NR^{f}R^{g}, or any combination thereof,
at least one of R¹ or R⁶ is a substituted or unsubstituted C6 to C20 aryl group, a substituted or unsubstituted C3 to C20 heterocyclic group, —NR^{f}R^{g}, or any combination thereof,
R^{a} to R^{g} are each independently hydrogen, a substituted or unsubstituted C1 to C30 alkyl group, a substituted or unsubstituted C6 to C20 aryl group, a substituted or unsubstituted C3 to C20 heterocyclic group, a halogen, a cyano group, or any combination thereof,
R^{a} and R^{b} are each independently present or are combined with each other to form a first ring,
R^{c} and R^{d} are each independently present or are combined with each other to form a second ring, and
R^{f} and R^{g} are each independently present or are combined with each other to form a third ring.

9. The image sensor of claim 8, wherein the first Pb-free perovskite comprises FA₁₋ₐMAₐSnI_{3-b-c}Cl_{b}Br_{c}, FA₁₋ₐEDAₐSnI_{3-b-c}Cl_{b}Br_{c}, FA₁₋ₐ(F-PEA)ₐSnI_{3-b-c}Cl_{b}Br_{c}, FA₁₋ₐ₁₋ₐ₂(MA)ₐ₁(EDA)ₐ₂SnI_{3-b-c}Cl_{b}Br_{c}, FA₁₋ₐ₁₋ₐ₂(MA)ₐ₁(Cs)ₐ₂SnI_{3-b-c}Cl_{b}Br_{c}, FA₁₋ₐ₁₋ₐ₂(EDA)ₐ₁(Cs)ₐ₂SnI_{3-b-c}Cl_{b}Br_{c}, FA₁₋ₐ₁₋ₐ₂(F-PEA)ₐ₁(Cs)ₐ₂SnI_{3-b-c}Cl_{b}Br_{c}, FA₁₋ₐ₁₋ₐ₂(MA)ₐ₁(EDA)ₐ₂SnI_{3-b-c}Cl_{b}Br_{c}, FA₁₋ₐ₁₋ₐ₂(F-PEA)ₐ₁(EDA)ₐ₂SnI_{3-b-c}Cl_{b}Br_{c}, FA₁₋ₐ₁₋ₐ₂(F-PEA)ₐ₁(MA)ₐ₂SnI_{3-b-c}Cl_{b}Br_{c}, or any combination thereof,
wherein FA is formamidinium, MA is methyl ammonium, EDA is ethylene diammonium, F-PEA is fluorine-substituted phenethylammonium, and
$$0 < a \leq 0.5 , 0 < ( a 1 + a 2 ) \leq 0.5 , 0 \leq a 1 \leq 0.5 , \\ 0 \leq a 2 \leq 0.5 , 0 \leq b \leq 0.5 , 0 \leq c \leq 0.5 , and 0 < ( b + c ) \leq 0.5 .$$

10. The image sensor of claim 8, wherein in Chemical Formula 2,
R¹ and R⁶ are each —NR^{f}R^{g}, wherein R^{f} and R^{g} are each a substituted or unsubstituted C6 to C20 aryl group,
R^{f} and R^{g} are bonded to form a ring through a single bond, a substituted or unsubstituted C1 to C5 alkylrene group, a substituted or unsubstituted C2 to C5 alkenylene group, a substituted or unsubstituted C6 to C20 arylene group, O, S, Se, Te, CR^{h}Rⁱ, SiRⁱR^{k}, or GeR^{l}R^{m}, and
R^{h} to R^{m} are each independently hydrogen, a substituted or unsubstituted C1 to C30 alkyl group, a substituted or unsubstituted C6 to C20 aryl group, a substituted or unsubstituted C3 to C20 heterocyclic group, a halogen, a cyano group, or any combination thereof.

11. The image sensor of claim 8, wherein the organic compound is represented by Chemical Formula 2A: 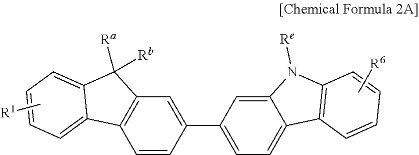
wherein, in Chemical Formula 2A,
R^{a} and R^{b} are each independently hydrogen, a substituted or unsubstituted C1 to C30 alkyl group or a substituted or unsubstituted C6 to C20 aryl group,
R^{e} is a substituted or unsubstituted C6 to C20 aryl group, and
R¹ and R⁶ are each one group of a plurality of groups listed in Group 1, 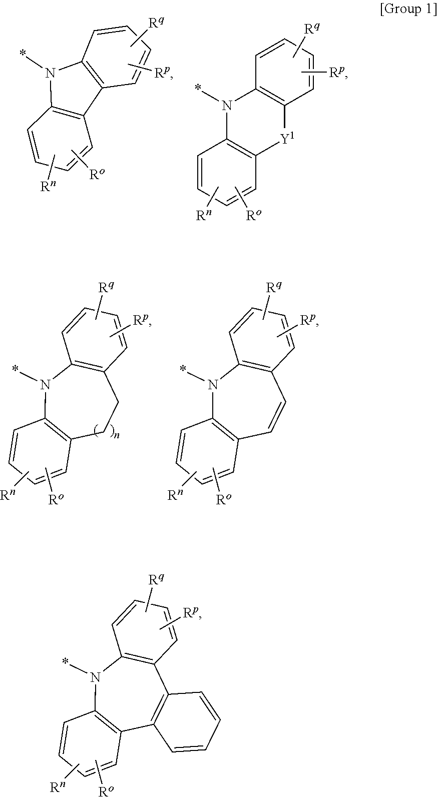
wherein, in Group 1,
Y¹ is O, S, Se, Te, CR^{h}Rⁱ, SiR^{j}R^{k}, or GeR^{l}R^{m},
R^{h} to R^{q} are each independently hydrogen, a substituted or unsubstituted C1 to C30 alkyl group, a substituted or unsubstituted C6 to C20 aryl group, a substituted or unsubstituted C3 to C20 heterocyclic group, a halogen, a cyano group, or any combination thereof,
n is an integer from 0 to 2, and
* is a linking point with Chemical Formula 2A.

12. The image sensor of claim 8, wherein the plurality of wavelength selective filters are at least two of a blue filter, a green filter, a red filter, a cyan filter, a yellow filter, a magenta filter, or an infrared filter.

13. The image sensor of claim 8, wherein the first perovskite photodiode comprises
a blue perovskite photodiode configured to selectively sense light in a blue wavelength spectrum,
a green perovskite photodiode configured to selectively sense light in a green wavelength spectrum, and
a red perovskite photodiode configured to selectively sense light in a red wavelength spectrum,
wherein the blue perovskite photodiode, the green perovskite photodiode, and the red perovskite photodiode are arranged along an in-plane direction of the substrate, and
the wavelength selective filter layer includes
a first wavelength selective filter overlapped with the blue perovskite photodiode in a vertical direction perpendicular to an upper surface of the substrate, the first wavelength selective filter one of a blue filter, a cyan filter, or a magenta filter,
a second wavelength selective filter overlapped with the green perovskite photodiode in the vertical direction, the second wavelength selective filter one of a green filter, a cyan filter, or a yellow filter, and
a third wavelength selective filter overlapped with the red perovskite photodiode in the vertical direction, the third wavelength selective filter one of a red filter, a yellow filter, or a magenta filter,
wherein the first wavelength selective filter, the second wavelength selective filter and the third wavelength selective filter are different from each other.

14. The image sensor of claim 13, wherein
the blue perovskite photodiode, the green perovskite photodiode, and the red perovskite photodiode include separate, respective portions of the first perovskite photoelectric conversion layer including the first Pb-free perovskite in common, and
a cut-off wavelength of an absorption spectrum of the first Pb-free perovskite belongs to more than about 650 nm and less than about 750 nm.

15. The image sensor of claim 13, wherein the first perovskite photodiode further comprises:
an infrared perovskite photodiode configured to selectively sense light of an infrared wavelength spectrum,
the infrared perovskite photodiode is arranged in parallel with the blue perovskite photodiode, the green perovskite photodiode, and the red perovskite photodiode along the in-plane direction of the substrate, and
the wavelength selective filter layer further comprises an infrared filter arranged in parallel with the first wavelength selective filter, the second wavelength selective filter, and the third wavelength selective filter, the infrared filter overlapped with the infrared perovskite photodiode in the vertical direction.

16. The image sensor of claim 15, wherein
the blue perovskite photodiode, the green perovskite photodiode, the red perovskite photodiode, and the infrared perovskite photodiode include separate, respective portions of the first perovskite photoelectric conversion layer, and
a cut-off wavelength of an absorption spectrum of the first Pb-free perovskite belongs to about 800 nm to about 3000 nm.

17. The image sensor of claim 8, further comprising an infrared photodiode stacked with the first perovskite photodiode in a vertical direction perpendicular to an upper surface of the substrate.

18. The image sensor of claim 17, wherein
the substrate is a CMOS substrate, and
the infrared photodiode is a silicon photodiode integrated in the CMOS substrate.

19. The image sensor of claim 17, wherein
the infrared photodiode is a second perovskite photodiode stacked with the first perovskite photodiode on the substrate, and
the second perovskite photodiode includes
a third electrode,
a fourth electrode,
a second perovskite photoelectric conversion layer between the third electrode and the fourth electrode, the second perovskite photoelectric conversion layer including a second Pb-free perovskite having a cut-off wavelength belonging to about 800 nm to about 3000 nm, and
a second auxiliary layer between the third electrode and the second perovskite photoelectric conversion layer and comprising the organic compound represented by Chemical Formula 2.

20. An electronic device comprising the image sensor of claim 8.
